(19) United States
(12) Patent Application Publication
(10) Pub. No.: US 2017/0299663 A1
(43) Pub. Date: Oct. 19, 2017

(54) MAGNETIC FIELD MEASUREMENT APPARATUS AND MAGNETIC FIELD MEASUREMENT METHOD

(71) Applicant: SEIKO EPSON CORPORATION, Tokyo (JP)

(72) Inventor: Kimio NAGASAKA, Hokuto-shi (JP)

(73) Assignee: SEIKO EPSON CORPORATION, Tokyo (JP)

(21) Appl. No.: 15/478,564

(22) Filed: Apr. 4, 2017

(30) Foreign Application Priority Data
Apr. 14, 2016 (JP) 2016-081356

(51) Int. Cl. G01R 33/032

(52) U.S. Cl. CPC G01R 33/032

(57) ABSTRACT

A magnetic field measurement apparatus includes at least one first magnetic sensor that measures a magnetic field including a magnetic field to be measured and an environmental magnetic field, a plurality of second magnetic sensors that measure the environmental magnetic field, and a magnetic field calculation unit that estimates distribution of the environmental magnetic field on the basis of measured values of the second magnetic sensors, and calculates the magnetic field to be measured on the basis of a measured value of the first magnetic sensor and the estimated distribution of the environmental magnetic field.

This application claims the benefit of Japanese Patent Application No. 2016-081356, filed on Apr. 14, 2016. The content of the aforementioned application is incorporated herein by reference in its entirety.

BACKGROUND

### 1. Technical Field

The present invention relates to a magnetic field measurement apparatus and a magnetic field measurement method.

### 2. Related Art

There have been known magnetic field measurement apparatuses for measuring a biomagnetic field such as a magnetic field of the heart (heart magnetic field) or a magnetic field of the brain (brain magnetic field) which is weaker than terrestrial magnetism. Since the magnetic field measurement apparatus is a non-invasive apparatus, it is possible to measure the state of an internal organ without placing burden on a test subject (living body). In such a type of magnetic field measurement apparatus, a biomagnetic field is measured by accommodating the test subject (living body) in a magnetic shielding apparatus in order to reduce the influence of magnetic noise such as terrestrial magnetism, but there is a concern that the accuracy of measurement is reduced due to the magnetic noise incapable of being shielded.

JP-A-2014-25715 discloses a method of calculating an offset component of a magnetic element and calibrating magnetic measurement data by reducing magnetic noise superimposed on the magnetic measurement data by using a statistical method.

However, in general, a biomagnetic field such as a heart magnetic field or a brain magnetic field is extremely weaker than an environmental magnetic field (magnetic noise), and thus it is difficult to secure a sufficient accuracy of measurement even when the method of JP-A-2014-25715 is applied to a measurement apparatus measuring such a week magnetic field.

### SUMMARY

An advantage of some aspects of the invention is to provide a magnetic field measurement apparatus capable of measuring even a week magnetic field with a sufficient accuracy, and a magnetic field measurement method.

The invention can be implemented as the following forms or application examples.

### Application Example 1

A magnetic field measurement apparatus according to this application example includes at least one first magnetic sensor that measures a magnetic field including a magnetic field to be measured and an environmental magnetic field, a plurality of second magnetic sensors that measure the environmental magnetic field, and a magnetic field calculation unit that estimates distribution of the environmental magnetic field on the basis of measured values of the second magnetic sensors, and calculates the magnetic field to be measured on the basis of a measured value of the first magnetic sensor and the estimated distribution of the environmental magnetic field.

According to the magnetic field measurement apparatus of this application example, the magnetic field calculation unit can calculate a magnetic field (magnetic field including a magnetic field to be measured and an environmental magnetic field) at the position of the first magnetic sensor on the basis of the measured value of the first magnetic sensor, and can calculate an environmental magnetic field at the position of the first magnetic sensor from the distribution of the environmental magnetic field which is estimated on the basis of the measured values of the plurality of second magnetic sensors. Therefore, for example, it is possible to calculate a difference between these magnetic fields or an approximate value thereof as the magnetic field to be measured. In this manner, according to the magnetic field measurement apparatus of this application example, a relatively large environmental magnetic field is estimated with a high level of accuracy even when the magnetic field to be measured is a week magnetic field, and thus it is possible to perform the measurement with a sufficient accuracy.

### Application Example 2

In the magnetic field measurement apparatus according to the application example, the magnetic field calculation unit may estimate a measured value of the environmental magnetic field which is obtained by the first magnetic sensor on the basis of a detected vector of the first magnetic sensor, positional information of the first magnetic sensor, and the estimated distribution of the environmental magnetic field, and may calculate the magnetic field to be measured on the basis of the measured value of the first magnetic sensor and the estimated measured value of the environmental magnetic field.

According to the magnetic field measurement apparatus of this application example, the magnetic field calculation unit can estimate the measured value of the environmental magnetic field which is obtained by the first magnetic sensor with a high level of accuracy by using the estimated distribution of the environmental magnetic field and the detected vector (information regarding the direction of a detection axis and a gain) or positional information of the first magnetic sensor. Therefore, for example, a difference between the measured value of the first magnetic sensor and the estimated measured value of the environmental magnetic field or an approximate value thereof can be calculated as the magnetic field to be measured with a high level of accuracy.

### Application Example 3

In the magnetic field measurement apparatus according to the application example, the magnetic field calculation unit may calculate an approximate value of a magnetic field at a position of the first magnetic sensor on the basis of the measured value of the first magnetic sensor and a gain of the first magnetic sensor, may calculate an approximate value of the environmental magnetic field at the position of the first magnetic sensor on the basis of the estimated measured value of the environmental magnetic field and the gain of the first magnetic sensor, and may calculate the magnetic field to be measured on the basis of a difference between the approximate value of the magnetic field at the position of the first magnetic sensor and the approximate value of the environmental magnetic field at the position of the first magnetic sensor.

According to the magnetic field measurement apparatus of this application example, for example, the magnetic field calculation unit can calculate a magnetic field (magnetic field including a magnetic field to be measured and an environmental magnetic field) in a detection axis direction at the position of the first magnetic sensor by dividing the measured value of the first magnetic sensor by a gain of the first magnetic sensor, and can calculate the environmental magnetic field in the detection axis direction at the position of the first magnetic sensor by dividing the estimated measured value of the environmental magnetic field by the gain of the first magnetic sensor. In a case where a deviation between the direction of a detection axis of the first magnetic sensor and a measurement direction is small, it is possible to set a calculated value of the magnetic field in the detection axis direction at the position of the first magnetic sensor to be an approximate value of the magnetic field at the position of the first magnetic sensor and to set a calculated value of the environmental magnetic field in the detection axis direction at the position of the first magnetic sensor to be an approximate value of the environmental magnetic field at the position of the first magnetic sensor. Therefore, according to the magnetic field measurement apparatus of this application example, even when the magnetic field to be measured cannot be correctly calculated due to the directions of the detection axes of all of the first magnetic sensors being aligned, the magnetic field calculation unit can perform approximation calculation of the magnetic field to be measured as a difference between the approximate value of the magnetic field (magnetic field including the magnetic field to be measured and the environmental magnetic field) at the position of the first magnetic sensor and the approximate value of the environmental magnetic field.

### Application Example 4

In the magnetic field measurement apparatus according to the application example, the magnetic field calculation unit may estimate the distribution of the environmental magnetic field on the basis of detected vectors of the second magnetic sensors, positional information of the second magnetic sensors, and the measured values of the second magnetic sensors.

According to the magnetic field measurement apparatus of this application example, the magnetic field calculation unit can estimate the distribution of the environmental magnetic field with a high level of accuracy by using the measured values of the second magnetic sensors and the detected vectors (information regarding the directions of detection axes and gains) or positional information of the second magnetic sensors.

### Application Example 5

The magnetic field measurement apparatus according to the application example may further include a calibration unit that estimates the distribution of the environmental magnetic field on the basis of the measured value of the first magnetic sensor and the measured values of the second magnetic sensors, and calculates the detected vector of the first magnetic sensor and the detected vectors of the second magnetic sensors on the basis of the estimated distribution of the environmental magnetic field.

According to the magnetic field measurement apparatus of this application example, for example, the calibration unit estimates the distribution of the environmental magnetic field in a space including the first magnetic sensor and the second magnetic sensors on the basis of the measured value of the first magnetic sensor and the measured values of the second magnetic sensors in a state where the magnetic field to be measured is not measured by the first magnetic sensor, and thus can calculate the detected vector (information regarding the direction of a detection axis and a gain) of the first magnetic sensor or the detected vectors (information regarding the directions of detection axes and gains) of the second magnetic sensors with a high level of accuracy. Therefore, according to the magnetic field measurement apparatus of this application example, the magnetic field calculation unit can calculate the magnetic field to be measured with a high level of accuracy by using the calculated detected vector (information regarding the direction of a detection axis and a gain) of the first magnetic sensor and the calculated detected vectors (information regarding the directions of detection axes and gains) of the second magnetic sensors.

### Application Example 6

In the magnetic field measurement apparatus according to the application example, the magnetic field calculation unit may estimate the distribution of the environmental magnetic field by approximating the environmental magnetic field by a polynomial expression with the position of the first magnetic sensor as a variable and calculating coefficients of the polynomial expression on the basis of the measured values of the second magnetic sensors.

According to the magnetic field measurement apparatus of this application example, the magnetic field calculation unit can approximate the environmental magnetic field at the position of the first magnetic sensor with a high level of accuracy by using the polynomial expression with the position of the first magnetic sensor as a variable, and can estimate the distribution of the environmental magnetic field at the position of the first magnetic sensor with a high level of accuracy in association with the coefficients of the polynomial expression which are calculated on the basis of the measured values of the second magnetic sensors.

### Application Example 7

In the magnetic field measurement apparatus according to the application example, the magnetic field calculation unit may calculate the coefficients of the polynomial expression on the assumption that divergence of the environmental magnetic field is zero.

According to the magnetic field measurement apparatus of this application example, it is possible to reduce the number of coefficients of the polynomial expression on the condition that the divergence of the environmental magnetic field is zero, and thus the amount of calculation of the magnetic field calculation unit is reduced, or the accuracy of calculation of the magnetic field to be measured is improved.

### Application Example 8

In the magnetic field measurement apparatus according to the application example, the magnetic field calculation unit may calculate the coefficients of the polynomial expression on the assumption that rotation of the environmental magnetic field is zero.

According to the magnetic field measurement apparatus of this application example, it is possible to reduce the number of coefficients of the polynomial expression on the condition that the rotation of the environmental magnetic field is zero, and thus the amount of calculation of the magnetic field calculation unit is reduced, or the accuracy of calculation of the magnetic field to be measured is improved.

### Application Example 9

In the magnetic field measurement apparatus according to the application example, at least two of the detected vectors of the second magnetic sensors may be perpendicular to each other.

According to the magnetic field measurement apparatus of this application example, it is possible to estimate the distribution of a planar environmental magnetic field or the distribution of a spatial environmental magnetic field in the vicinity of the second magnetic sensors with a higher level of accuracy than in a case where all of the detected vectors (detection axes) of the second magnetic sensors face in the same direction, thereby improving the accuracy of calculation of the magnetic field to be measured.

### Application Example 10

In the magnetic field measurement apparatus according to the application example, each of the first magnetic sensor and the second magnetic sensors may include a cell which accommodates alkali metal atoms and on which linearly polarized light is incident, a polarized light separator that separates light emitted from the cell into light in a first axis direction and light in a second axis direction, a first light detector that detects the light in the first axis direction, and a second light detector that detects the light in the second axis direction.

According to this application example, it is possible to realize the magnetic field measurement apparatus capable of measuring even a week magnetic field with a sufficient accuracy by using an optically pumped type magnetic sensor as the first magnetic sensor and the second magnetic sensor.

### Application Example 11

In the magnetic field measurement apparatus according to the application example, the cells included in the second magnetic sensors maybe disposed on the same plane.

According to this application example, it is possible to accommodate the cells of the plurality of second magnetic sensors in one container (heat insulating mechanism) and keep the cells warm and to simplify a branching mechanism for light to each cell, and thus manufacturing costs of the magnetic field measurement apparatus can be reduced.

### Application Example 12

A magnetic field measurement method according to this application example includes acquiring a measured value of at least one first magnetic sensor that measures a magnetic field including a magnetic field to be measured and an environmental magnetic field, acquiring measured values of a plurality of second magnetic sensors that measure the environmental magnetic field, estimating distribution of the environmental magnetic field on the basis of the measured values of the second magnetic sensors, and calculating the magnetic field to be measured on the basis of the measured value of the first magnetic sensor and the estimated distribution of the environmental magnetic field.

According to the magnetic field measurement method of this application example, it is possible to calculate a magnetic field (magnetic field including a magnetic field to be measured and an environmental magnetic field) at the position of the first magnetic sensor on the basis of the measured value of the first magnetic sensor and to calculate an environmental magnetic field at the position of the first magnetic sensor from the distribution of the environmental magnetic field which is estimated on the basis of the measured values of the plurality of second magnetic sensors. Therefore, for example, it is possible to calculate a difference between these magnetic fields or an approximate value thereof as the magnetic field to be measured. In this manner, according to the magnetic field measurement method of this application example, a relatively large environmental magnetic field is estimated with a high level of accuracy even when the magnetic field to be measured is a week magnetic field, and thus it is possible to perform the measurement with a sufficient accuracy.

### BRIEF DESCRIPTION OF THE DRAWINGS

The invention will be described with reference to the accompanying drawings, wherein like numbers reference like elements.

FIG. 1 is a schematic side view illustrating a configuration example of a magnetic field measurement apparatus according to this embodiment.

FIG. 2 is a schematic side view of a magnetic sensor unit.

FIG. 3 is a schematic plan view of the magnetic sensor unit.

FIG. 4 is a diagram illustrating a configuration example of a processing apparatus.

FIG. 5 is a diagram illustrating a calibration method of the magnetic field measurement apparatus according to this embodiment.

FIG. 6 is a flow chart illustrating an example of a procedure in which a calibration unit of the processing apparatus performs a calibration process.

FIG. 7 is a block diagram corresponding to processes of step S3 to step S7 of FIG. 6.

FIG. 8 is a flow chart illustrating an example of a procedure of a process of updating a detected vector matrix.

FIG. 9 is a diagram illustrating a magnetic field measurement method according to this embodiment.

FIG. 10 is a flow chart illustrating an example of a procedure in which a magnetic field calculation unit of the processing apparatus performs a magnetic field calculation process.

### DESCRIPTION OF EXEMPLARY EMBODIMENTS

Hereinafter, preferred embodiments of the invention will be described in detail with reference the accompanying drawings. Meanwhile, the embodiments described below are not unduly limited to the disclosure of the invention described in the appended claims. In addition, all the configurations described below are not necessarily essential components of the invention.

### 1. First Embodiment

1-1. Configuration of Magnetic Field Measurement Apparatus

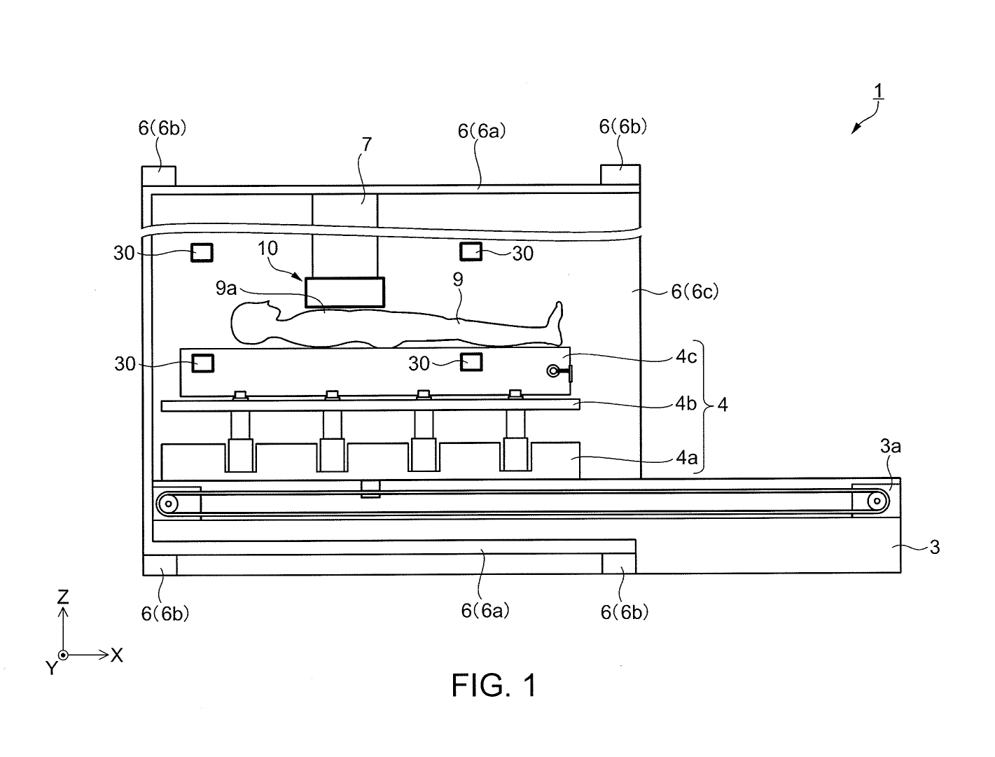

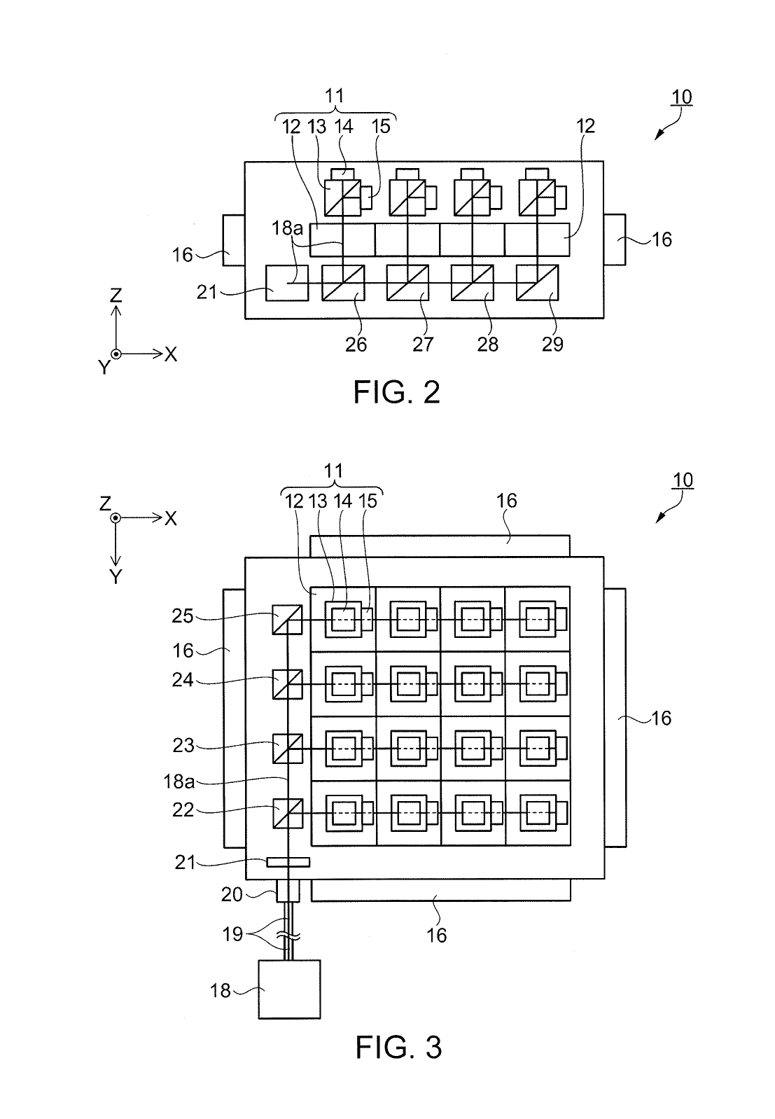

FIG. 1 is a schematic side view illustrating a configuration example of a magnetic field measurement apparatus according to this embodiment. As illustrated in FIG. 1, a magnetic field measurement apparatus 1 of this embodiment is an apparatus that measures, as a measurement object, a heart magnetic field generated from the heart of a test subject (living body) 9, or a brain magnetic field generated from the brain of the test subject (living body) 9, and the like. As illustrated in FIG. 1, the magnetic field measurement apparatus 1 includes a magnetic sensor unit 10 including at least one first magnetic sensor 11 (see FIGS. 2, 3, and 5) which is not shown in the drawing, a plurality of second magnetic sensors 30, a processing apparatus 2 (see FIG. 5) which is not shown in the drawing, a base 3, a table 4, and a magnetic shielding apparatus 6.

The first magnetic sensor 11 included in the magnetic sensor unit 10 is a sensor that measures a magnetic field including a week magnetic field (a magnetic field to be measured) such as a heart magnetic field or a brain magnetic field which serves as a measurement object and an environmental magnetic field such as an external magnetic field (magnetic noise), and is used as a magnetocardiograph, a magnetoencephalography, or the like. The second magnetic sensor 30 is a sensor that measures an environmental magnetic field such as an external magnetic field (magnetic noise). As the first magnetic sensor 11 and the second magnetic sensor 30, an optically pumped type magnetic sensor, a SQUID type magnetic sensor, a flux gate magnetic sensor, a MI sensor, a Hall element, or the like can be used.

The height direction (up-down direction in FIG. 1) of the magnetic field measurement apparatus 1 is set to be a Z-direction. The Z-direction is a vertical direction. Directions in which the upper surfaces of the base 3 and the table 4 extend are set to be an X-direction and a Y-direction. The X-direction and the Y-direction are horizontal directions, and are perpendicular to each other. The stature direction (right-left direction in FIG. 1) of the test subject 9 who is lying down is set to be the X-direction.

The base 3 is disposed on the bottom surface on the inner side of the magnetic shielding apparatus 6 (main body portion 6a), and extends along the X-direction (movable direction of the test subject 9) up to the outside of the main body portion 6a. The table 4 includes an X-direction table 4a, a Z-direction table 4b, and a Y-direction table 4c. The X-direction table 4a, moving along the X-direction by an X-direction linear motion mechanism 3a, is installed on the base 3. The Z-direction table 4b, which is elevated along the Z-direction by an elevation apparatus not shown in the drawing, is installed on the X-direction table 4a. The Y-direction table 4c, moving along the Y-direction on a rail by a Y-direction linear motion mechanism not shown in the drawing, is installed on the Z-direction table 4b.

The magnetic shielding apparatus 6 includes the main body portion 6a, having a square tubular shape, which includes an opening portion 6c. The inside of the main body portion 6a is hollow, and the cross-sectional shape of a surface (plane perpendicular to the X-direction in a Y-Z cross-section) which passes through the Y-direction and the Z-direction is substantially a quadrangular shape. When a heart magnetic field is measured, the test subject 9 is accommodated in the main body portion 6a in a state of lying on the table 4. The main body portion 6a extends in the X-direction, and functions as a passive magnetic shield by itself.

The magnetic sensor unit 10 and the second magnetic sensors 30 are disposed inside the main body portion 6a of the magnetic shielding apparatus 6. The magnetic shielding apparatus 6 suppresses a situation in which an external magnetic field such as terrestrial magnetism flows into a space for disposing the magnetic sensor unit 10. That is, the space for disposing the magnetic sensor unit 10 is set to be in a state of a magnetic field significantly lower than the external magnetic field by the magnetic shielding apparatus 6, and thus the influence of the external magnetic field on the magnetic sensor unit 10 is suppressed.

The base 3 protrudes in the +X-direction from the opening portion 6c of the main body portion 6a. Regarding the size of the magnetic shielding apparatus 6, for example, the length in the X-direction is approximately 200 cm, and one side of the opening portion 6c is approximately 90 cm. The test subject 9 lying on the table 4 can move on the base 3 together with the table 4 along the X-direction to enter the magnetic shielding apparatus 6 from the opening portion 6c.

The processing apparatus 2 not shown in the drawing is an apparatus that receives an electrical signal from the first magnetic sensor 11 included in the magnetic sensor unit 10 and an electrical signal from the second magnetic sensor 30 to thereby measures a magnetic field such as a heart magnetic field or a brain magnetic field. A magnetic field or a residual magnetic field which is generated by an electrical signal, generated by the processing apparatus 2, and is detected by the magnetic sensor unit 10 changes to noise. For this reason, it is preferable that the processing apparatus 2 is installed at a location apart from the opening portion 6c of the magnetic shielding apparatus 6 so that a generated magnetic field or a residual magnetic field hardly reaches the magnetic sensor unit 10.

The main body portion 6a of the magnetic shielding apparatus 6 is formed of, for example, a ferromagnetic body having a relative permeability of several thousands or more or a conductor with high conductivity. As the ferromagnetic body, Permalloy, ferrite, iron-, chromium-, or cobalt-based amorphous, or the like can be used. As the conductor with high conductivity, a conductor such as aluminum which has an effect of reducing a magnetic field by an eddy current effect can be used. Meanwhile, it is also possible to form the main body portion 6a by alternately laminating the ferromagnetic body and the conductor with high conductivity.

A correction coil (Helmholtz coil) 6b is installed at an end on the +X-direction side of the main body portion 6a and on the −X-direction side of the base 3. The correction coil 6b has a frame shape and is disposed so as to surround the main body portion 6a. The correction coil 6b is a coil for correcting an inflow magnetic field that flows into the internal space of the main body portion 6a. The inflow magnetic field indicates a magnetic field which is an external magnetic field that passes through the opening portion 6c and enters the internal space. The inflow magnetic field becomes strongest in the X-direction with respect to the opening portion 6c. The correction coil 6b generates a magnetic field so as to cancel the inflow magnetic field by a current supplied from the processing apparatus 2.

The magnetic sensor unit 10 is fixed to the ceiling of the main body portion 6a through a supporting member 7. The magnetic sensor unit 10 measures an intensity component of a magnetic field in the Z-direction. That is, the detection axis of each of the first magnetic sensors 11 included in the magnetic sensor unit 10 faces in the Z-direction. When a heart magnetic field of the test subject 9 is measured, the X-direction table 4a and the Y-direction table 4c are moved so that a chest 9a which is a measurement position in the test subject 9 is set to be at a position facing the magnetic sensor unit 10, and the Z-direction table 4b is lifted up so that the chest 9a approaches the magnetic sensor unit 10.

The plurality of second magnetic sensors 30 are disposed in the vicinity of the magnetic sensor unit 10. Each of the second magnetic sensors 30 measures components of a magnetic field in the X-direction, the Y-direction, or the Z-direction. That is, the detection axis of each of the second magnetic sensors 30 faces in the X-direction, the Y-direction, or the Z-direction.

1-2. Configuration of Magnetic Sensor Unit

FIGS. 2 and 3 are schematic diagrams illustrating the structure of the magnetic sensor unit 10 according to this embodiment. In detail, FIG. 2 is a schematic side view of the magnetic sensor unit 10, and FIG. 3 is a schematic plan view of the magnetic sensor unit 10.

As illustrated in FIG. 3, a laser beam 18a is supplied to the magnetic sensor unit 10 from a laser light source 18. The laser beam 18a emitted from the laser light source 18 is supplied to the magnetic sensor unit 10 via an optical fiber 19. The magnetic sensor unit 10 and the optical fiber 19 are connected to each other through an optical connector 20.

The laser light source 18 outputs the laser beam 18a having a wavelength based on an absorption line of cesium. The wavelength of the laser beam 18a is not particularly limited, but is set to, for example, a wavelength of 894 nm equivalent to a D1 line in this embodiment. The laser light source 18 is a tunable laser, and the laser beam 18a which is output from the laser light source 18 is a continuous light having a fixed amount of light.

The laser beam 18a supplied through the optical connector 20 advances in the −Y-direction to be incident on a polarizing plate 21. The laser beam 18a having passed through the polarizing plate 21 changes to linearly polarized light. The laser beam 18a is sequentially incident on a first half mirror 22, a second half mirror 23, a third half mirror 24, and a first reflective mirror 25.

The first half mirror 22, the second half mirror 23, and the third half mirror 24 reflect a portion of the laser beam 18a to advance the reflected beam in the +X-direction, and transmit a portion of the laser beam 18a to advance the transmitted beam in the −Y-direction. The first reflective mirror 25 reflects the entire incident laser beam 18a in the +X-direction. The laser beam 18a is split into four light paths by the first half mirror 22, the second half mirror 23, the third half mirror 24, and the first reflective mirror 25. The reflectances of the respective mirrors are set so that the light intensities of the laser beam 18a in the respective light paths are set to be the same light intensity.

Next, as illustrated in FIG. 2, the laser beam 18a is sequentially incident on a fourth half mirror 26, a fifth half mirror 27, a sixth half mirror 28, and a second reflective mirror 29. The fourth half mirror 26, the fifth half mirror 27, and the sixth half mirror 28 reflect a portion of the laser beam 18a to advance the reflected beam in the +Z-direction, and transmit a portion of the laser beam 18a to advance the transmitted beam in the +X-direction. The second reflective mirror 29 reflects the entire incident laser beam 18a in the +Z-direction.

One light path of the laser beam 18a is split into four light paths by the fourth half mirror 26, the fifth half mirror 27, the sixth half mirror 28, and the second reflective mirror 29. The reflectances of the respective mirrors are set so that the light intensities of the laser beam 18a in the respective light paths are set to be the same light intensity. Therefore, the laser beam 18a is divided into 16 light paths. The reflectances of the respective mirrors are set so that the light intensities of the laser beam 18a in the respective light paths are set to be the same intensity.

Here, 16 gas cells 12 of four rows by four columns are installed in the light paths of the laser beam 18a on the +Z-direction sides of the fourth half mirror 26, the fifth half mirror 27, the sixth half mirror 28, and the second reflective mirror 29. The laser beam 18a reflected by the fourth half mirror 26, the fifth half mirror 27, the sixth half mirror 28, and the second reflective mirror 29 passes through the gas cells 12. The gas cell 12 is a box having voids therein, and gas of an alkali metal is enclosed in the voids. The alkali metal is not particularly limited, and potassium, rubidium, or cesium can be used. In this embodiment, for example, cesium can be used for the alkali metal.

A polarized light separator 13 is installed on the +Z-direction side of each of the gas cells 12. The polarized light separator 13 is an element that separates the incident laser beam 18a into laser beams 18a of two polarization components perpendicular to each other. For example, a Wollaston prism or a polarization beam splitter can be used for the polarized light separator 13.

A first light detector 14 is installed on the +Z-direction side of the polarized light separator 13, and a second light detector 15 is installed on the +X-direction side of the polarized light separator 13. The laser beam 18a having passed through the polarized light separator 13 is incident on the first light detector 14, and the laser beam 18a reflected by the polarized light separator 13 is incident on the second light detector 15. Each of first light detector 14 and the second light detector 15 outputs a current based on the light intensity of the incident laser beam 18a to the processing apparatus 2.

Since there is a possibility that the generation of a magnetic field by the first light detector 14 and the second light detector 15 affects measurement, it is preferable that the first light detector 14 and the second light detector 15 are formed of a nonmagnetic material. The magnetic sensor unit 10 includes heaters 16 which are installed on both surface in the X-direction and both surface in the Y-direction. It is preferable that the heater 16 is configured not to generate a magnetic field. For example, it is possible to use a type of heater that performs heating by making vapor or hot air pass through a flow passage. Instead of the heater, the dielectric heating of the gas cell 12 may be performed by a high frequency voltage.

The magnetic sensor unit 10 is disposed on the +Z-direction side of the test subject 9 (see FIG. 1). A magnetic vector generated by the test subject 9 enters the magnetic sensor unit 10 from the −Z-direction side. The magnetic vector passes through the fourth half mirror 26 to the second reflective mirror 29, passes through the gas cells 12, and passes through the polarized light separators 13 to come out of the magnetic sensor unit 10.

The cesium in the gas cell 12 is heated to be in a gas state. The cesium gas is irradiated with the laser beam 18a transformed into linearly polarized light, thereby exciting cesium atoms and aligning the direction of magnetic moment. When the magnetic vector passes through the gas cells 12 in this state, the magnetic moment of the cesium atoms precesses by the magnetic field of the magnetic vector. This precession is referred to as Larmor precession.

The magnitude of the Larmor precession has a positive correlation with the intensity of the magnetic field of the magnetic vector. The Larmor precession rotates a deflected surface of the laser beam 18a. The magnitude of the Larmor precession and the amount of variation in a rotation angle of the deflected surface of the laser beam 18a have a positive correlation. Therefore, the intensity of the magnetic field and the amount of variation in the rotation angle of the deflected surface of the laser beam 18a have a positive correlation.

The polarized light separator 13 separates the laser beam 18a into linearly polarized light beams of two components perpendicular to each other. The first light detector 14 and the second light detector 15 detect the intensity of the linearly polarized light beams of the two components perpendicular to each other. Thereby, the first light detector 14 and the second light detector 15 can detect the rotation angle of the deflected surface of the laser beam 18a. The processing apparatus 2 can calculate a magnetic field from a variation in the rotation angle of the deflected surface of the laser beam 18a.

The first magnetic sensor 11 is constituted by the gas cell 12, the polarized light separator 13, the first light detector 14, and the second light detector 15. The first magnetic sensor 11 is a sensor referred to as an optically pumped type magnetic sensor or an optically pumped atom magnetic sensor. The sensitivity of the first magnetic sensor 11 is high in the Z-direction and is low in a direction perpendicular to the Z-direction. As illustrated in FIG. 3, for example, 16 first magnetic sensors 11 of four rows by four columns are disposed in the magnetic sensor unit 10. The number of first magnetic sensors 11 and the arrangement thereof in the magnetic sensor unit 10 are not particularly limited. The number of rows of the first magnetic sensors 11 may be three or less or may be five or more. Similarly, the number of columns of the first magnetic sensors 11 may be three or less or may be five or more. As the number of first magnetic sensors 11 increases, the spatial resolution can be increased.

The external magnetic field flowing into a measurement object space for disposing the magnetic sensor unit 10 is suppressed by the magnetic shielding apparatus 6 (see FIG. 1), but it is difficult to completely eliminate the inflow of the external magnetic field. In other words, a magnetic field (heart magnetic field) and an environmental magnetic field (magnetic noise) which are to be measured are applied to the magnetic sensor unit 10. For this reason, a measured value obtained by measurement performed by the first magnetic sensor 11 includes a signal component based on the magnetic field (heart magnetic field) to be measured and a noise component based on the environmental magnetic field (magnetic noise) to be measured. Therefore, it is necessary to remove the noise component from the measured value obtained by the first magnetic sensor 11 with a high level of accuracy in order to accurately acquire the magnetic field (heart magnetic field) to be measured.

1-3. Configuration of Second Magnetic Sensor

The second magnetic sensor 30 is a sensor for measuring an environmental magnetic field (magnetic noise) in a measurement object space in which the magnetic sensor unit 10 is disposed. The environmental magnetic field (magnetic noise) in the measurement object space is specified from a measured value obtained by the second magnetic sensor 30, and thus it is possible to remove the component of the environmental magnetic field (magnetic noise) from a measured value obtained by the first magnetic sensor 11. It is assumed that the second magnetic sensor 30 detects an environmental magnetic field (magnetic noise) and does not detect a magnetic field (heart magnetic field) to be measured.

All of the detection axes of the plurality of second magnetic sensors 30 may face in the Z-direction, but it is preferable that at least two detection axes among the detection axes (detected vectors k_{β1} to k_{βN} to be described later) of the plurality of second magnetic sensors 30 are perpendicular to each other. For example, the detection axis of at least one second magnetic sensor 30 may face in the Z-direction, and the detection axes of the other second magnetic sensors 30 may face in the X-direction or the Y-direction. Thereby, it is possible to estimate the distribution of a planar environmental magnetic field or the distribution of a spatial environmental magnetic field in the vicinity of the second magnetic sensors 30 with a higher level of accuracy than in a case where all of the detection axes of the second magnetic sensors 30 face in the Z-direction, thereby improving the accuracy of calculation of a magnetic field by a magnetic field measurement method to be described later according to this embodiment.

Although the type of sensor used as the second magnetic sensor 30 is not limited, it is possible to use, for example, an optically pumped type magnetic sensor which is the same as the first magnetic sensor 11 mentioned above. That is, similarly to the first magnetic sensor 11, the second magnetic sensor 30 may include the cell (gas cell 12) which accommodates alkali metal atoms and on which linearly polarized light is incident, the polarized light separator 13 that separates light emitted from the cell into light in a first axis direction and light in a second axis direction, the first light detector 14 that detects the light in the first axis direction, and the second light detector 15 that detects the light in the second axis direction.

It is preferable that the cells (equivalent to the gas cells 12 of FIGS. 2 and 3) which are included in the second magnetic sensors 30 are disposed on the same plane. In this manner, it is possible to accommodate the cells of the plurality of second magnetic sensors 30 in one container (heat insulating mechanism) and keep the cells warm and to simplify a branching mechanism for a laser beam to each cell, and thus manufacturing costs of the magnetic field measurement apparatus 1 can be reduced.

1-4. Configuration of Processing Apparatus

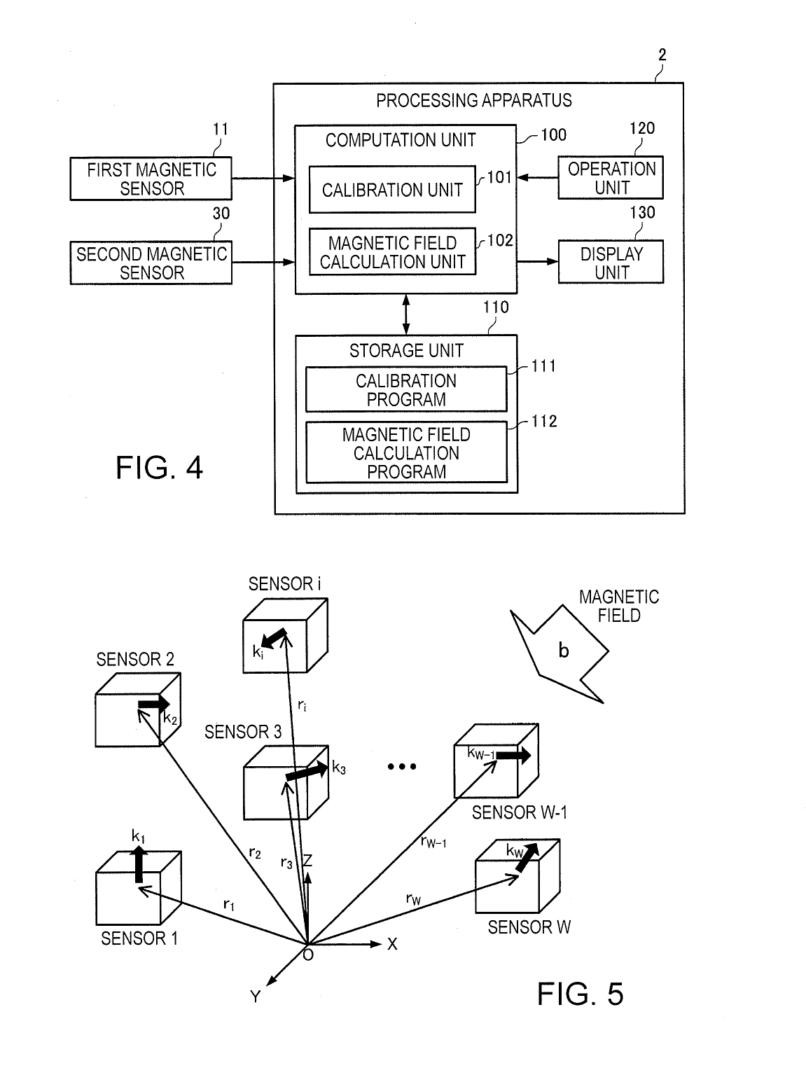

FIG. 4 is a diagram illustrating a configuration example of the processing apparatus 2. As illustrated in FIG. 4, the processing apparatus 2 is configured to include a computation unit 100, a storage unit 110, an operation unit 120, and a display unit 130.

The operation unit 120 is a unit for inputting information (various instructions such as an instruction for starting to measure a magnetic field and measurement conditions) which is necessary for a process performed by the computation unit 100, and may be any of various switches such as a button switch, a lever switch, and a dial switch, a touch panel, a keyboard, a mouse, or the like.

The display unit 130 is a unit that displays processing results of the computation unit 100 as characters, a graph, a table, an animation, or other images, and may be, for example, a liquid crystal display (LCD), an electroluminescence (EL) display, or the like.

Meanwhile, the functions of the operation unit 120 and the display unit 130 may be realized by one touch panel type display.

The storage unit 110 is a unit for storing programs, data, and the like for the computation unit 100 to perform various processes, and is constituted by any of various IC memories such as a read only memory (ROM), a flash ROM, and a random access memory (RAM), a recording medium such as a hard disk or a memory card, or the like.

Particularly, in this embodiment, the storage unit 110 stores a calibration program 111 which is read by the computation unit 100 and is used to perform a calibration process of the magnetic field measurement apparatus 1, and a magnetic field calculation program 112 for performing a process of calculating a magnetic field to be measured (magnetic field calculation process). The calibration program 111 and the magnetic field calculation program 112 may be stored in the storage unit 110 in advance, or the computation unit 100 may receive the calibration program 111 and the magnetic field calculation program 112 from a server through a network and store in the storage unit 110.

In addition, the storage unit 110 is used as a work area of the computation unit 100, and temporarily stores results of computation performed by the computation unit 100 in accordance with various programs, and the like. Further, the storage unit 110 may store data required to be stored for a long period of time among pieces of data generated by the processing of the computation unit 100.

The computation unit 100 is realized, for example, by a microprocessor such as a central processing unit (CPU), and performs the above-described calibration process, magnetic field calculation process, and the like.

In this embodiment, the computation unit 100 functions as a calibration unit 101 by executing the calibration program 111. That is, the calibration program 111 is a program for causing the processing apparatus 2 (computer) to function as the calibration unit 101 (alternatively, for causing the processing apparatus 2 to perform a calibration process). The calibration unit 101 acquires a measured value of the first magnetic sensor 11 and a measured value of the second magnetic sensor 30 to thereby perform a calibration process of the magnetic field measurement apparatus 1. Details of this calibration process will be described later.

In addition, in this embodiment, the computation unit 100 functions as a magnetic field calculation unit 102 by executing the magnetic field calculation program 112. That is, the magnetic field calculation program 112 is a program for causing the processing apparatus 2 (computer) to function as the magnetic field calculation unit 102 (alternatively, for causing the processing apparatus 2 to perform a calibration process). The magnetic field calculation unit 102 acquires a measured value of the first magnetic sensor 11 and a measured value of the second magnetic sensor 30 to thereby perform a magnetic field calculation process. Details of this magnetic field calculation process will be described later.

1-5. Calibration Process of Magnetic Field Measurement Apparatus

After a calibration method of the magnetic field measurement apparatus according to this embodiment is described in detail, a procedure in which the calibration unit 101 of the processing apparatus 2 performs a calibration process corresponding to the calibration method will be described.

The calibration method according to this embodiment is not limited to the first magnetic sensor 11 or the second magnetic sensor 30, and can be applied to a magnetic field measurement apparatus including any magnetic sensor. Hereinafter, in order to give a description expanded to a more general concept, the first magnetic sensor 11 and the second magnetic sensor 30 will be simply referred to as a “magnetic sensor” without making a distinction therebetween.

As illustrated in FIG. 5, it is assumed that the number of magnetic sensors W, and a detected vector kᵢ and a position vector rᵢ of each magnetic sensor i (i=1 to W) have any value. The detected vector kᵢ is a vector indicating a product of a unit vector of each magnetic sensor i in a detection axis direction and a gain of each magnetic sensor i, and the position vector rᵢ is a vector indicating a distance between a starting point O and the position of each magnetic sensor i. The calibration process of the magnetic field measurement apparatus 1 is a process of obtaining detected vectors k₁ to k_{W} of W magnetic sensors.

As illustrated in FIG. 5, a magnetic field b is applied to W magnetic sensors. It is assumed that the magnetic field b includes not only a uniform magnetic field but also a high-order gradient magnetic field. The magnetic field b for calibration may be a magnetic field which is artificially formed, or may be a natural magnetic field such as terrestrial magnetism.

Ideally, components bₓ^{(t)}, b_{y}^{(t)}, and b_{z}^{(t)} of a computational magnetic field at any point (x, y, z) at time t are made to conform to the order of distribution of a magnetic field to be measured. However, in this embodiment, it is assumed that the components are expressed by a secondary nonlinear polynomial expression of the following expression (1).

bₓ^{(t)}=aₓ₁^{(t)}+aₓ₂^{(t)}x+aₓ₃^{(t)}y+aₓ₄^{(t)}z+aₓ₅^{(t)}xy+aₓ₆^{(t)}yz+aₓ₇^{(t)}zx+aₓ₈^{(t)}x²+aₓ₉^{(t)}y²+aₓ₁₀^{(t)}z²

b_{y}^{(t)}=a_{y1}^{(t)}+a_{y2}^{(t)}x+a_{y3}^{(t)}y+a_{y4}^{(t)}z+a_{y5}^{(t)}xy+a_{y6}^{(t)}yz+a_{y7}^{(t)}zx+a_{y8}^{(t)}x²+a_{y9}^{(t)}y²+a_{y10}^{(t)}z²

b_{z}^{(t)}=a_{z1}^{(t)}+a_{z2}^{(t)}x+a_{z3}^{(t)}y+a_{z4}^{(t)}z+a_{z5}^{(t)}xy+a_{z6}^{(t)}yz+a_{z7}^{(t)}zx+a_{z8}^{(t)}x²+a_{z9}^{(t)}y²+a_{z10}^{(t)}z² (1)

Here, when a calculated magnetic field value at the position of the magnetic sensor i at time t is set to be (bᵢₓ^{(t)}, b_{iy}^{(t)}, b_{iz}^{(t)}), a calculated magnetic field value vector b^{(t)} at the position of each of W magnetic sensors at the time t is expressed by the following expression (2).

\vec{b}^{(t)}=(b₁ₓ^{(t)} b_{1y}^{(t)} b_{1z}^{(t)} b₂ₓ^{(t)} b_{2y}^{(t)} . . . b_{Wx}^{(t)} b_{Wy}^{(t)} b_{Wz}^{(t)}) (2)

When calculated magnetic field value vectors b⁽¹⁾ to b^{(T)} at times t=1 to T are integrated, a calculated magnetic field value matrix B is expressed by the following expression (3). Meanwhile, in Expression (3), tr represents the transposition of the vector.

$$B = ( \begin{matrix}{\vec{b}}^{( 1 ) tr} & {\vec{b}}^{( 2 ) tr} & … & {\vec{b}}^{( T ) tr}\end{matrix} ) = ( \begin{matrix}{b}_{1 x}^{( 1 )} & {b}_{1 x}^{( 2 )} & {b}_{1 x}^{( 3 )} & … & {b}_{1 x}^{( T )} \\ {b}_{1 y}^{( 1 )} & {b}_{1 y}^{( 2 )} & {b}_{1 y}^{( 3 )} & … & {b}_{1 y}^{( T )} \\ {b}_{1 z}^{( 1 )} & {b}_{1 z}^{( 2 )} & {b}_{1 z}^{( 3 )} & … & {b}_{1 z}^{( T )} \\ {b}_{2 x}^{( 1 )} & {b}_{2 x}^{( 2 )} & {b}_{2 x}^{( 3 )} & … & {b}_{2 x}^{( T )} \\ {b}_{2 y}^{( 1 )} & {b}_{2 y}^{( 2 )} & {b}_{2 y}^{( 3 )} & … & {b}_{2 y}^{( T )} \\ ⋮ & ⋮ & ⋮ & ⋮ & ⋮ \\ {b}_{Wx}^{( 1 )} & {b}_{Wx}^{( 2 )} & {b}_{Wx}^{( 3 )} & … & {b}_{Wx}^{( T )} \\ {b}_{Wy}^{( 1 )} & {b}_{Wy}^{( 2 )} & {b}_{Wy}^{( 3 )} & … & {b}_{Wy}^{( T )} \\ {b}_{Wz}^{( 1 )} & {b}_{Wz}^{( 2 )} & {b}_{Wz}^{( 3 )} & … & {b}_{Wz}^{( T )}\end{matrix} ) \qquad ( 3 )$$

Next, as shown in the following expression (4), a set of coefficients of the polynomial expression (1) is represented by a 30-dimensional column vector a^{(t)}. Meanwhile, in Expression (4), tr represents the transposition of the vector.

\vec{a}^{(t)}=(aₓ₁^{(t)} aₓ₂^{(t)} . . . aₓ₉^{(t)} aₓ₁₀^{(t)} a_{y1}^{(t)}a_{y2}^{(t)} . . . a_{y9}^{(t)} a_{y10}^{(t)} . . . a_{z1}^{(t)} a_{z2}^{(t)} . . . a_{z9}^{(t)} a_{z10}^{(t)})^{tr} (4)

Since it is assumed that the vector a^{(t)} varies in time series, a polynomial expression coefficient matrix A obtained by integrating vectors a⁽¹⁾ to a^{(T)} at times t=1 to T is defined as the following expression (5). Meanwhile, in Expression (5), tr represents the transposition of the vector.

$$A = ( \begin{matrix}{\vec{a}}^{( 1 ) tr} & {\vec{a}}^{( 2 ) tr} & {\vec{a}}^{( 3 ) tr} & … & {\vec{a}}^{( T ) tr}\end{matrix} ) = ( \begin{matrix}{a}_{x 1}^{( 1 )} & {a}_{x 1}^{( 2 )} & {a}_{x 1}^{( 3 )} & … & {a}_{x 1}^{( T )} \\ {a}_{x 2}^{( 1 )} & {a}_{x 2}^{( 2 )} & {a}_{x 2}^{( 3 )} & … & {a}_{x 2}^{( T )} \\ ⋮ & ⋮ & ⋮ & ⋮ & ⋮ \\ {a}_{x 9}^{( 1 )} & {a}_{x 9}^{( 2 )} & {a}_{x 9}^{( 3 )} & … & {a}_{x 9}^{( T )} \\ {a}_{x 10}^{( 1 )} & {a}_{x 10}^{( 2 )} & {a}_{x 10}^{( 3 )} & … & {a}_{x 10}^{( T )} \\ {a}_{y 1}^{( 1 )} & {a}_{y 1}^{( 2 )} & {a}_{y 1}^{( 3 )} & … & {a}_{y 1}^{( T )} \\ {a}_{y 2}^{( 1 )} & {a}_{y 2}^{( 2 )} & {a}_{y 2}^{( 3 )} & … & {a}_{y 2}^{( T )} \\ ⋮ & ⋮ & ⋮ & ⋮ & ⋮ \\ {a}_{y 9}^{( 1 )} & {a}_{y 9}^{( 2 )} & {a}_{y 9}^{( 3 )} & … & {a}_{y 9}^{( T )} \\ {a}_{y 10}^{( 1 )} & {a}_{y 10}^{( 2 )} & {a}_{y 10}^{( 3 )} & … & {a}_{y 10}^{( T )} \\ {a}_{z 1}^{( 1 )} & {a}_{z 1}^{( 2 )} & {a}_{z 1}^{( 3 )} & … & {a}_{z 1}^{( T )} \\ {a}_{z 2}^{( 1 )} & {a}_{z 2}^{( 2 )} & {a}_{z 2}^{( 3 )} & … & {a}_{z 2}^{( T )} \\ ⋮ & ⋮ & ⋮ & ⋮ & ⋮ \\ {a}_{z 9}^{( 1 )} & {a}_{z 9}^{( 2 )} & {a}_{z 9}^{( 3 )} & … & {a}_{z 9}^{( T )} \\ {a}_{z 10}^{( 1 )} & {a}_{z 10}^{( 2 )} & {a}_{z 10}^{( 3 )} & … & {a}_{z 10}^{( T )}\end{matrix} ) \qquad ( 5 )$$

A positional information matrix P of 3 W×30 is defined as the following expression (6) on the basis of the defined secondary nonlinear polynomial expression (1).

$$P = ( \begin{matrix}1 & {x}_{1} & … & {y}_{1}^{2} & {z}_{1}^{2} & 0 & 0 & … & 0 & 0 & 0 & 0 & … & 0 & 0 \\ 0 & 0 & … & 0 & 0 & 1 & {x}_{1} & … & {y}_{1}^{z} & {z}_{1}^{z} & 0 & 0 & … & 0 & 0 \\ 0 & 0 & … & 0 & 0 & 0 & 0 & … & 0 & 0 & 1 & {x}_{1} & … & {y}_{1}^{2} & {z}_{1}^{2} \\ 1 & {x}_{2} & … & {y}_{2}^{2} & {z}_{2}^{2} & 0 & 0 & … & 0 & 0 & 0 & 0 & … & 0 & 0 \\ 0 & 0 & … & 0 & 0 & 1 & {x}_{2} & … & {y}_{2}^{2} & {z}_{2}^{2} & 0 & 0 & … & 0 & 0 \\ 0 & 0 & … & 0 & 0 & 0 & 0 & … & 0 & 0 & 1 & {x}_{2} & … & {y}_{2}^{2} & {z}_{2}^{2} \\ 1 & {x}_{3} & … & {y}_{3}^{2} & {z}_{3}^{2} & 0 & 0 & … & 0 & 0 & 0 & 0 & … & 0 & 0 \\ ⋮ & ⋮ & ⋮ & ⋮ & ⋮ & ⋮ & ⋮ & ⋮ & ⋮ & ⋮ & ⋮ & ⋮ & ⋮ & ⋮ & ⋮ \\ 1 & {x}_{W} & … & {y}_{W}^{2} & {z}_{W}^{2} & 0 & 0 & … & 0 & 0 & 0 & 0 & … & 0 & 0 \\ 0 & 0 & … & 0 & 0 & 1 & {x}_{W} & … & {y}_{W}^{2} & {z}_{W}^{2} & 0 & 0 & … & 0 & 0 \\ 0 & 0 & … & 0 & 0 & 0 & 0 & … & 0 & 0 & 1 & {x}_{W} & … & {y}_{W}^{2} & {z}_{W}^{2}\end{matrix} ) \qquad ( 6 )$$

Here, the following relational expression (7) is established. That is, the positional information matrix P is a matrix for converting the position vectors r₁ to r_{W} of W magnetic sensors into the calculated magnetic field value matrix B.

B=PA (7)

In addition, a gain matrix G including gains (equivalent to sensitivities) g₁ to g_{W} of W magnetic sensors as elements is defined as the following expression (8). The gain matrix G is a square matrix of W×W.

$$G = ( \begin{matrix}{g}_{1} & 0 & … & 0 \\ ⋮ & ⋮ & ⋮ & ⋮ \\ 0 & {g}_{2} & … & 0 \\ 0 & 0 & … & {g}_{W}\end{matrix} ) \qquad ( 8 )$$

In addition, a detection axis orientation of the magnetic sensor i is represented by a unit vector (sᵢₓ, s_{iy}, s_{iz}) on an XYZ orthogonal coordinate system, and a detection axis matrix S of W×3W which is obtained by integrating the unit vectors of the detection axis orientations of W magnetic sensors is defined as the following expression (9). Meanwhile, the relation of sᵢₓ²+s_{iy}²+s_{iz}²=1 is established.

$$S = ( \begin{matrix}{s}_{1 x} & {s}_{1 y} & {s}_{1 z} & 0 & 0 & … & 0 & 0 & 0 \\ 0 & 0 & 0 & {s}_{2 x} & {s}_{2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {s}_{Wx} & {s}_{Wy} & {s}_{Wz}\end{matrix} ) \qquad ( 9 )$$

As shown in the following expression (10), a product of the gain matrix G and the detection axis matrix S is set to be a detected vector matrix K. Here, the detected vector kᵢ of the magnetic sensor i is (gᵢsᵢₓ, gᵢs_{iy}, gᵢs_{iz}), and the detected vector matrix K includes the detected vectors k₁ to k_{W} of W magnetic sensors as elements.

$$GS = ( \begin{matrix}{g}_{1} {s}_{1 x} & {g}_{1} {s}_{1 y} & {g}_{1} {s}_{1 z} & 0 & 0 & … & 0 & 0 & 0 \\ 0 & 0 & 0 & {g}_{2} {s}_{s x} & {g}_{2} {s}_{2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {g}_{W} {s}_{W x} & {g}_{W} {s}_{Wy} & {g}_{W} {s}_{W z}\end{matrix} ) = K \qquad ( 10 )$$

In addition, a computational observation value (estimated value) of the magnetic sensor i at time t is represented by a calculated observation value lᵢ^{(t)}′, and a calculated observation value vector l^{(t)}′ obtained by integrating calculated observation values l₁^{(t)}′ to l_{W}^{(t)}′ of W magnetic sensors at time t is defined as the following expression (11). Meanwhile, in Expression (11), tr represents the transposition of the vector.

l^{(t)′}=(l₁^{(t)′}l₂^{(t)′} . . . l_{W}^{(t)′})^{tr} (11)

At this time, a relational expression of the following expression (12) is established between a calculated observation value matrix L′ obtained by integrating calculated observation value vectors l⁽¹⁾′ to l^{(T)}′ at times t=1 to T, the detected vector matrix K, the positional information matrix P, and the polynomial expression coefficient matrix A. In Expression (12), the relation of D=KP is established.

L′=KPA=DA (12)

Similarly, an actual observation value (actual measurement value) of the magnetic sensor i at time t is represented by a sensor observation value lᵢ^{(t)}, and a sensor observation value vector l^{(t)} obtained by integrating sensor observation values l₁^{(t)} to l_{W}^{(t)} of W magnetic sensors at time t is defined as the following expression (13). Meanwhile, in Expression (13), tr represents the transposition of the vector.

\vec{l}^{(t)}=(l₁^{(t)} l₂^{(t)} . . . l_{W}^{(t)})^{tr} (13)

As shown in the following expression (14), a difference between the sensor observation value vector l^{(t)} and the calculated observation value vector l^{(t)′ i}s set to be an observation value error vector v^{(t)}.

\vec{v}^{(t)}=\vec{l}^{(t)}−\vec{l}^{(t)′} (14)

In addition, when a matrix obtained by integrating observation value error vectors v⁽¹⁾ to v^{(T)} at times t=1 to T is set to be an observation value error matrix V, the observation value error matrix V is represented by a difference between a sensor observation value matrix L obtained by integrating sensor observation value vectors l⁽¹⁾ to l^{(T)} at times t=1 to T and the calculated observation value matrix L′ as shown in the following expression (15).

V=L−L′ (15)

When an optimization problem for obtaining the detected vector matrix K for minimizing a norm ∥V∥ of the observation value error matrix V defined as the following expression (16) and the polynomial expression coefficient matrix A is solved, the detected vectors k₁ to k_{W} of W magnetic sensors are obtained. However, the convergence of the solution of the optimization problem may require a long time, and thus it is realistic to obtain the detected vectors k₁ to k_{W} when the norm ∥V∥ of the observation value error matrix V becomes smaller than an allowable value ε.

∥V∥=(Σₜ₌₁^{T}Σᵢ₌₁^{W}|ᵢ^{(t)}|²)^{1/2}=(Σₜ₌₁^{T}∥\vec{v}^{(t)}∥²)^{1/2} (16)

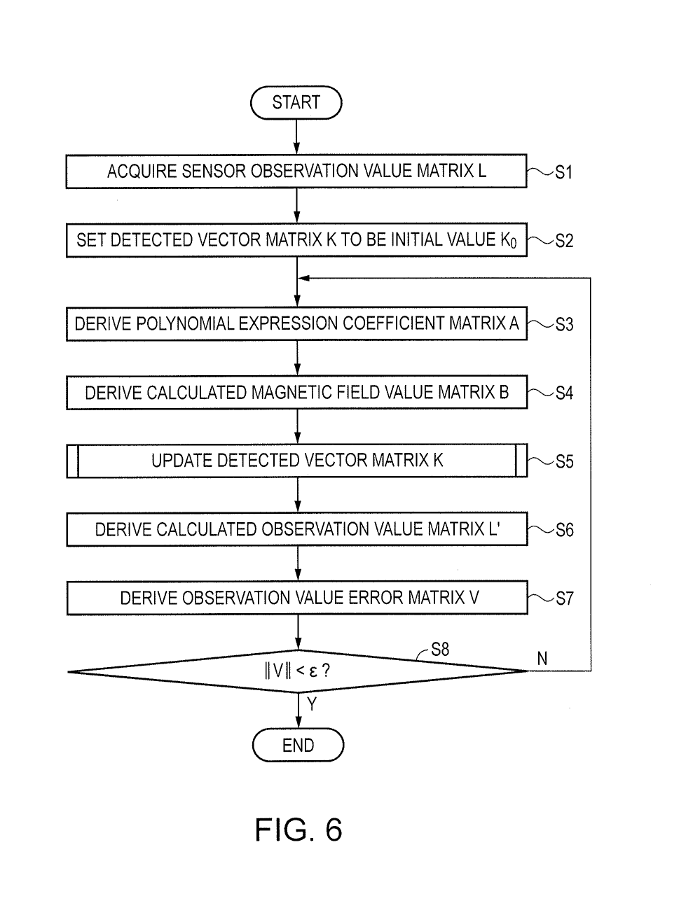

FIG. 6 is a flow chart illustrating an example of a procedure in which the calibration unit 101 (see FIG. 4) of the processing apparatus 2 performs a calibration process corresponding to the above-described calibration method of the magnetic field measurement apparatus 1. Meanwhile, the calibration process of FIG. 6 is performed in a state where the test subject (living body) 9 is not lying on the table 4 (a state where there is no influence of a heart magnetic field or a brain magnetic field from the test subject (living body) 9).

In the example of FIG. 6, first, the calibration unit 101 acquires the sensor observation value matrix L (step S1). Specifically, the calibration unit 101 acquires measured values of the respective first magnetic sensors 11 and measured values of the respective second magnetic sensors 30 at t=1 to T, and acquires the sensor observation value matrix L obtained by integrating these measured values as sensor observation value vectors l⁽¹⁾ to l^{(T)}.

Next, the calibration unit 101 sets the detected vector matrix K to be an initial value K₀ (step S2). In order to converge the detected vector matrix K to a value approximate to a true value by the processes of steps S3 to S8 to be described later, it is preferable that the initial value K₀ is a value having a small difference from the true value and may be, for example, a design value (value estimated from the arrangement of the first magnetic sensors 11 and the arrangement of the second magnetic sensors). Meanwhile, the values of respective elements of the initial value K₀ are stored in the storage unit 110 in advance.

Next, the calibration unit 101 derives the polynomial expression coefficient matrix A (step S3). Specifically, the calibration unit 101 derives the polynomial expression coefficient matrix A from the sensor observation value matrix L acquired in step S1, the detected vector matrix K (initial value K₀ which is set in step S2), and the positional information matrix P by the following expression (17). Meanwhile, the values of respective elements of the positional information matrix P are stored in the storage unit 110 in advance.

A=(KP)⁺L=D⁺L (17)

In Expression (17), (KP)⁺ is a pseudo inverse matrix of KP, and D⁺ is a pseudo inverse matrix of D(=KP). A pseudo inverse matrix D⁺(=(KP)⁺) is defined as the following expression (18). Meanwhile, in Expression (18), T represents the transposition of the matrix.

D⁺=(D^{T}D)⁻¹D^{T} (18)

Next, the calibration unit 101 derives the calculated magnetic field value matrix B (step S4). Specifically, the calibration unit 101 derives the calculated magnetic field value matrix B from the polynomial expression coefficient matrix A derived in step S3 and the positional information matrix P by Expression (7).

Next, the calibration unit 101 updates the detected vector matrix K (step S5). Specifically, the calibration unit 101 derives a matrix corresponding to a matrix product of the sensor observation value matrix L acquired in step S1 and a pseudo inverse matrix B⁺of the calculated magnetic field value matrix B derived in step S4 and updates the detected vector matrix K. However, actually, the detected vector matrix K may not be correctly derived even when the matrix product of the sensor observation value matrix L and the pseudo inverse matrix B⁺ is calculated. Accordingly, in this embodiment, the detected vector matrix K is updated by deriving the detected vectors k₁ to k_{W} which are elements of the detected vector matrix K from sensor observation value vectors l₁ to l_{W} which are elements of the sensor observation value matrix L and calculated magnetic field value matrices bₗ to b_{W} which are elements of the calculated magnetic field value matrix B. Details of this process of updating the detected vector matrix K will be described later.

Next, the calibration unit 101 derives the calculated observation value matrix L′ (step S6). Specifically, the calibration unit 101 derives the calculated observation value matrix L′ from the calculated magnetic field value matrix B derived in step S4 and the detected vector matrix K updated in step S5 by the following expression (19).

L′=KB (19)

Next, the calibration unit 101 derives the observation value error matrix V (step S7). Specifically, the calibration unit 101 derives the observation value error matrix V from the sensor observation value matrix L acquired in step S1 and the calculated observation value matrix L′ derived in step S3 by Expression (15).

Next, the calibration unit 101 determines whether or not the norm ∥V∥ of the observation value error matrix V is smaller than the allowable value ε (step S8). Specifically, the calibration unit 101 calculates the norm ∥V∥ from the observation value error matrix V derived in step S3 by Expression (16), and compares the calculated value with the allowable value ε.

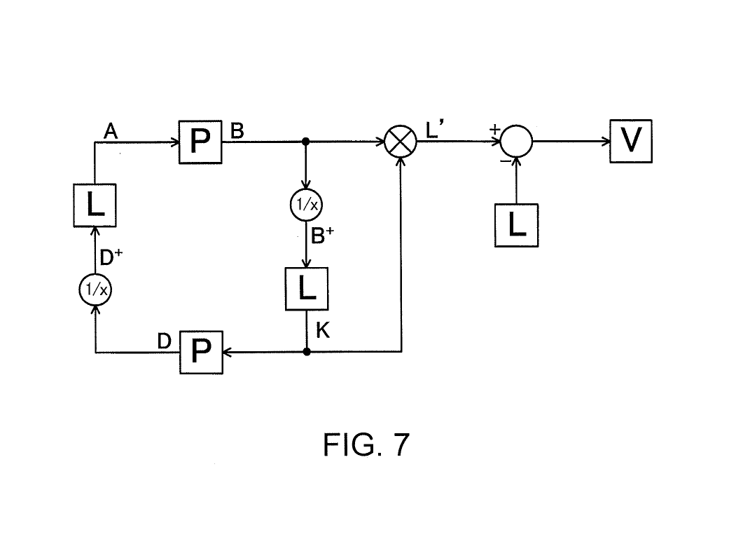

In a case where the norm ∥V∥ is equal to or greater than the allowable value ε (N instep S8), the calibration unit 101 performs the process of step S3 and the subsequent processes again. When the norm ∥V∥ becomes smaller than the allowable value ε (Y in step S8), the calibration unit terminates the calibration process. Meanwhile, FIG. 7 is a block diagram corresponding to the processes of steps S3 to S7 of FIG. 6.

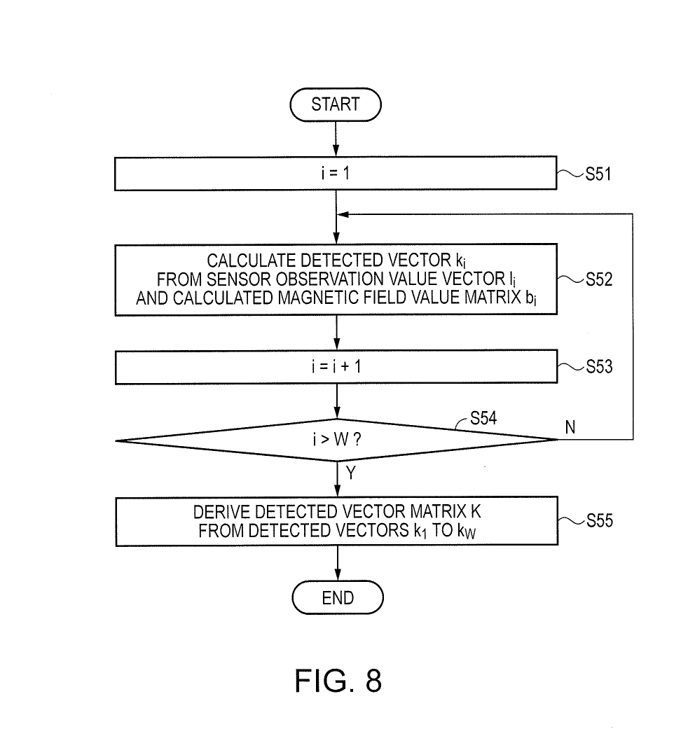

FIG. 8 is a flow chart illustrating an example of a procedure of a process of updating the detected vector matrix K (the process of step S5 of FIG. 6).

In the example of FIG. 8, first, the calibration unit 101 initializes a variable i to 1 (step S51).

Next, the calibration unit 101 calculates a detected vector kᵢ from a sensor observation value vector lᵢ and a calculated magnetic field value matrix bᵢ (step S52). Specifically, the calibration unit 101 calculates the detected vector kᵢ from the sensor observation value vector lᵢ and the calculated magnetic field value matrix bᵢ by the following expression (20). Meanwhile, in Expression (20), T represents the transposition of the vector.

\vec{k}ᵢ=\vec{l}ᵢbᵢ^{T}(bᵢbᵢ^{T})⁻¹ (20)

Here, the sensor observation value vector lᵢ is defined as a vector obtained by integrating sensor observation values lᵢ⁽¹⁾ to lᵢ^{(T)} at times t=1 to T on the basis of a magnetic sensor i as shown in the following expression (21), and the sensor observation value matrix L is a matrix obtained by integrating sensor observation value vectors l₁ to l_{W} as in Expression (22).

$$\begin{matrix}{\vec{l}}_{i} = ( \begin{matrix}{l}_{i}^{( 1 )} & {l}_{i}^{( 2 )} & … & {l}_{i}^{( T )}\end{matrix} ) & ( 21 ) \\ L = ( \begin{matrix}{l}_{1}^{( 1 )} & {l}_{1}^{( 2 )} & … & {l}_{1}^{( T )} \\ {l}_{2}^{( 1 )} & {l}_{2}^{( 2 )} & … & {l}_{2}^{( T )} \\ ⋮ & ⋮ & ⋮ & ⋮ \\ {l}_{W}^{( 1 )} & {l}_{W}^{( 2 )} & … & {l}_{W}^{( T )}\end{matrix} ) = ( \begin{matrix}{\vec{l}}_{1} \\ {\vec{l}}_{2} \\ ⋮ \\ {\vec{l}}_{W}\end{matrix} ) & ( 22 )\end{matrix}$$

In addition, the calculated magnetic field value matrix bᵢ is defined as a vector obtained by integrating calculated magnetic field values at the positions of the magnetic sensors i at times t=1 to T as shown in the following expression (23), and the calculated magnetic field value matrix B is a matrix obtained by integrating the calculated magnetic field value matrices b₁ to b_{W} as in Expression (24).

$$\begin{matrix}{b}_{i} = ( \begin{matrix}{b}_{ix}^{( 1 )} & {b}_{ix}^{( 2 )} & {b}_{ix}^{( 3 )} & … & {b}_{ix}^{( T )} \\ {b}_{iy}^{( 1 )} & {b}_{iy}^{( 2 )} & {b}_{iy}^{( 3 )} & … & {b}_{iy}^{( T )} \\ {b}_{iz}^{( 1 )} & {b}_{iz}^{( 2 )} & {b}_{iz}^{( 3 )} & … & {b}_{iz}^{( T )}\end{matrix} ) & ( 23 ) \\ B = ( \begin{matrix}{b}_{1 x}^{( 1 )} & {b}_{1 x}^{( 2 )} & {b}_{1 x}^{( 3 )} & … & {b}_{1 x}^{( T )} \\ {b}_{1 y}^{( 1 )} & {b}_{1 y}^{( 2 )} & {b}_{1 y}^{( 3 )} & … & {b}_{1 y}^{( T )} \\ {b}_{1 z}^{( 1 )} & {b}_{1 z}^{( 2 )} & {b}_{1 z}^{( 3 )} & … & {b}_{1 z}^{( T )} \\ {b}_{2 x}^{( 1 )} & {b}_{2 x}^{( 2 )} & {b}_{2 x}^{( 3 )} & … & {b}_{2 x}^{( T )} \\ {b}_{2 y}^{( 1 )} & {b}_{2 y}^{( 2 )} & {b}_{2 y}^{( 3 )} & … & {b}_{2 y}^{( T )} \\ {b}_{2 yz}^{( 1 )} & {b}_{2 z}^{( 2 )} & {b}_{2 z}^{( 3 )} & … & {b}_{2 z}^{( T )} \\ ⋮ & ⋮ & ⋮ & ⋮ & ⋮ \\ {b}_{Wx}^{( 1 )} & {b}_{Wx}^{( 2 )} & {b}_{Wx}^{( 3 )} & … & {b}_{Wx}^{( T )} \\ {b}_{Wy}^{( 1 )} & {b}_{Wy}^{( 2 )} & {b}_{Wy}^{( 3 )} & … & {b}_{Wy}^{( T )} \\ {b}_{Wz}^{( 1 )} & {b}_{Wz}^{( 2 )} & {b}_{Wz}^{( 3 )} & … & {b}_{Wz}^{( T )}\end{matrix} ) = ( \begin{matrix}{b}_{1} \\ {b}_{2} \\ ⋮ \\ {b}_{W}\end{matrix} ) & ( 24 )\end{matrix}$$

Next, the calibration unit 101 increments the variable i by 1 (step S53).

Next, the calibration unit 101 determines whether or not the variable i is greater than W (step S54). That is, the calibration unit 101 determines whether or not the calculation of each of the detected vectors k₁ to k_{W} has been terminated.

In a case where the variable i is equal to or less than W (N in step S54), the calibration unit 101 performs the process of step S52 and the subsequent processes again. When the variable i becomes larger than W (Y in step S54), the calibration unit derives a detected vector matrix K from the detected vectors k₁ to k_{W}, and terminates the process of updating the detected vector matrix K. As described above, the detected vector kᵢ is (gᵢsᵢₓ, gᵢs_{iy}, gᵢs_{iz}) and the calibration unit 101 derives the detected vector matrix K by integrating the detected vectors k₁ to k_{W}, as in Expression (10) (step S55).

1-6. Magnetic Field Measurement Process

After a magnetic field measurement method according to this embodiment is described in detail, a procedure in which the magnetic field calculation unit 102 of the processing apparatus 2 performs a magnetic field calculation process corresponding to the magnetic field measurement method will be described.

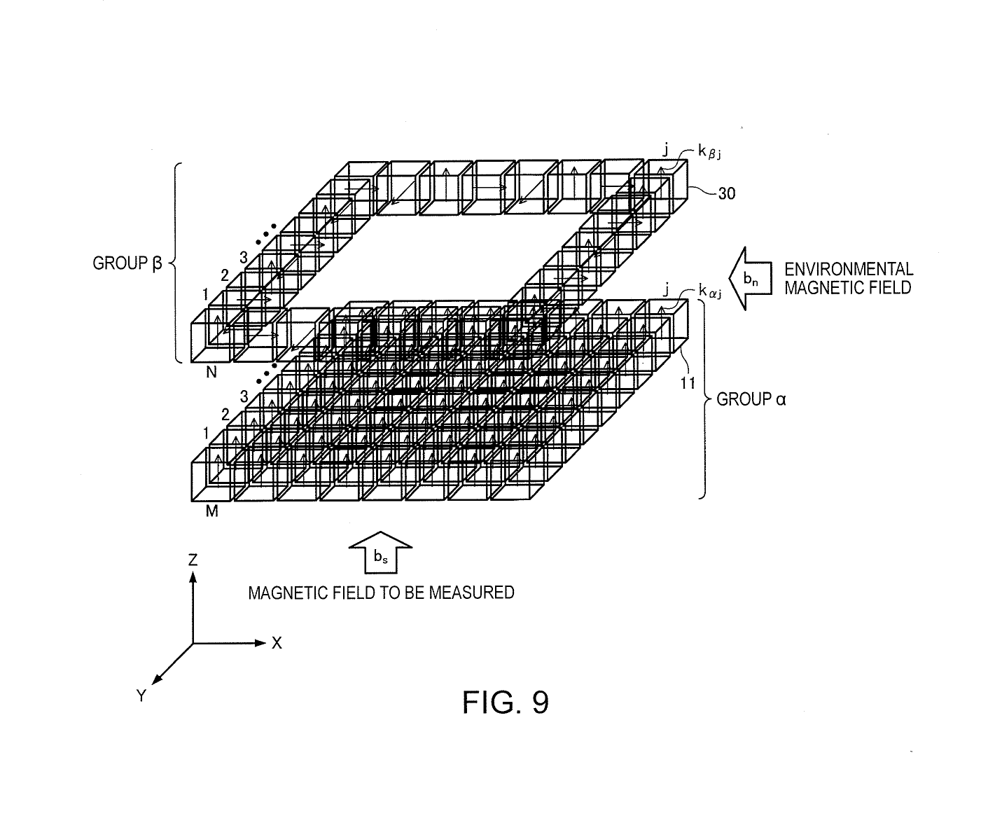

As illustrated in FIG. 9, it is assumed that a group α constituted by M magnetic sensors (equivalent to the first magnetic sensors 11) arranged in an array and a group β constituted by N magnetic sensors (equivalent to the second magnetic sensors 30) dispersed or arranged in an array are present in a space represented by an XYZ orthogonal coordinate system (referred to as an absolute coordinate system). Each of the magnetic sensors constituting the group α simultaneously measures a magnetic field bₛ (heart magnetic field) and an environmental magnetic field bₙ (magnetic noise) to be measured, and each of the magnetic sensors constituting the group β measures the environmental magnetic field bₙ (magnetic noise). Meanwhile, the number of magnetic sensors of the group β is two or more (N≧2), but the number of magnetic sensors of the group α may be one (M=1) or may be two or more (M≧2).

Each magnetic sensor i is a vector type magnetic sensor that outputs a single-axis component, and has an inherent detected vector kᵢ. The length of the detected vector kᵢ indicates a gain in the whole system, and the orientation thereof indicates a shading axis. It is assumed that a sensor observation value vector lᵢ which is a measured value obtained by each magnetic sensor i is represented by an inner product of a magnetic field applied to the magnetic sensor i and the detected vector kᵢ.

In addition, the environmental magnetic field bₙ applied to the magnetic sensor varies every moment, and includes not only a uniform magnetic field but also a high-order gradient magnetic field. The environmental magnetic field bₙ may be a magnetic field which is artificially formed, or may be a natural magnetic field such as terrestrial magnetism. In addition, the distribution of a magnetic field may also be distorted by magnetic substance in the vicinity of the magnetic sensor.

Ideally, components (bₙᵢₓ, b_{niy}, b_{niz}) of a computational environmental magnetic field at any position (xᵢ, yᵢ, zᵢ) at any point in time are made to conform to the order of distribution of a magnetic field to be measured. In this embodiment, it is assumed that the components are expressed by a secondary nonlinear polynomial expression of the following expression (25).

bₙᵢₓ=aₓᵢ+aₓ₂xᵢ+aₓ₃yᵢ+aₓ₄zᵢ+aₓ₅xᵢyᵢ+aₓ₆yᵢzᵢ+aₓ₇zᵢxᵢ+aₓ₈xᵢ²+aₓ₉yᵢ²+aₓ₁₀zᵢ²

b_{niy}=a_{yi}+a_{y2}xᵢ+a_{y3}yᵢ+a_{y4}zᵢ+a_{y5}xᵢyᵢ+a_{y6}yᵢzᵢ+a_{y7}zᵢxᵢ+a_{y8}xᵢ²+a_{y9}yᵢ²+a_{y10}zᵢ²

b_{niz}=a_{z1}+a_{z2}xᵢ+a_{z3}yᵢ+a_{z4}zᵢ+a_{z5}xᵢyᵢ+a_{z6}yᵢzᵢ+a_{z7}zᵢxᵢ+a_{z8}xᵢ²+a_{z9}yᵢ²+a_{z10}zᵢ² (25)

When a calculated magnetic field value of the environmental magnetic field bₙ at a position (xⱼ, yⱼ, zⱼ) of a magnetic sensor j of the group β is set to be (bₙⱼₓ, b_{njy}, b_{njz}), a calculated magnetic field value vector B_{nβ} at the positions of N magnetic sensors of the group β is expressed by the following expression (26).

\vec{B}_{nβ}=(bₙ₁ₓ b_{n1y} b_{n1z} bₙ₂ₓ b_{n2y} . . . b_{nNx} b_{nNy} b_{nNz}) (26)

Next, as shown in the following expression (27), a set of coefficients of the polynomial expression (26) is represented by a 30-dimensional column vector (polynomial expression coefficient vector) a. Meanwhile, in Expression (27), tr represents the transposition of the vector.

\vec{a}=(aₓ₁ aₓ₂ . . . aₓ₉ aₓ₁₀ a_{y1} a_{y2} . . . a_{y9} a_{y10} . . . a_{z1} a_{z2} . . . a_{z9} a_{z10})^{tr} (27)

A positional information matrix P_{β} of 3N×30 is defined as the following expression (28) on the basis of the defined secondary nonlinear polynomial expression (25).

$${P}_{β} = ( \begin{matrix}1 & {x}_{1} & … & {y}_{1}^{2} & {z}_{1}^{2} & 0 & 0 & … & 0 & 0 & 0 & 0 & … & 0 & 0 \\ 0 & 0 & … & 0 & 0 & 1 & {x}_{1} & … & {y}_{1}^{2} & {z}_{1}^{2} & 0 & 0 & … & 0 & 0 \\ 0 & 0 & … & 0 & 0 & 0 & 0 & … & 0 & 0 & 1 & {x}_{1} & … & {y}_{1}^{2} & {z}_{1}^{2} \\ 1 & {x}_{2} & … & {y}_{2}^{2} & {z}_{2}^{2} & 0 & 0 & … & 0 & 0 & 0 & 0 & … & 0 & 0 \\ 0 & 0 & … & 0 & 0 & 1 & {x}_{2} & … & {y}_{2}^{2} & {z}_{2}^{2} & 0 & 0 & … & 0 & 0 \\ 0 & 0 & … & 0 & 0 & 0 & 0 & … & 0 & 0 & 1 & {x}_{2} & … & {y}_{2}^{2} & {z}_{2}^{2} \\ 1 & {x}_{3} & … & {y}_{3}^{2} & {z}_{3}^{2} & 0 & 0 & … & 0 & 0 & 0 & 0 & … & 0 & 0 \\ ⋮ & ⋮ & ⋮ & ⋮ & ⋮ & ⋮ & ⋮ & ⋮ & ⋮ & ⋮ & ⋮ & ⋮ & ⋮ & ⋮ & ⋮ \\ 1 & {x}_{N} & … & {y}_{N}^{2} & {z}_{N}^{2} & 0 & 0 & … & 0 & 0 & 0 & 0 & … & 0 & 0 \\ 0 & 0 & … & 0 & 0 & 1 & {x}_{N} & … & {y}_{N}^{2} & {z}_{N}^{2} & 0 & 0 & … & 0 & 0 \\ 0 & 0 & … & 0 & 0 & 0 & 0 & … & 0 & 0 & 1 & {x}_{N} & … & {y}_{N}^{2} & {z}_{N}^{2}\end{matrix} ) \qquad ( 28 )$$

Here, the following relational expression (29) is established. That is, the positional information matrix P_{β} is a matrix for converting position vectors r₁=(x₁, y₁, z₁) to r_{N}=(x_{N}, y_{N}, z_{N}) of N magnetic sensors of the group β into the calculated magnetic field value vector B_{nβ}.

\vec{B}_{nβ}=P_{β}\vec{a} (29)

In addition, a gain matrix G_{β} including gains (equivalent to sensitivities) g_{β1} to g_{βN} of N magnetic sensors of the group β as elements is defined as the following expression (30). The gain matrix G_{β} is a square matrix of N×N.

$${G}_{β} = ( \begin{matrix}{g}_{β1} & 0 & … & 0 \\ ⋮ & ⋮ & ⋮ & ⋮ \\ 0 & {g}_{β2} & … & 0 \\ 0 & 0 & … & {g}_{β N}\end{matrix} ) \qquad ( 30 )$$

In addition, a detection axis orientation of the magnetic sensor j of the group β is represented by a unit vector s_{βj}=(s_{βjx}, s_{βjy}, s_{βjz}) on an XYZ orthogonal coordinate system, and a detection axis matrix S_{β} of N×3N which is obtained by integrating the unit vectors s_{β1} to s_{βN} of the detection axis orientations of N magnetic sensors of the group β is defined as the following expression (31). Meanwhile, the relation of s_{βjz}²+s_{βjy}²+s_{βjz}²=1 is established.

$${S}_{β} = ( \begin{matrix}{s}_{β1 x} & {s}_{β1 y} & {s}_{β1 z} & 0 & 0 & … & 0 & 0 & 0 \\ 0 & 0 & 0 & {s}_{β2 x} & {s}_{β2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {s}_{β Nx} & {s}_{β Ny} & {s}_{β Nz}\end{matrix} ) \qquad ( 31 )$$

As shown in the following expression (32), a product of the gain matrix G_{β} and the detection axis matrix S_{β} is set to be a detected vector matrix K_{β}. Here, a detected vector k_{βj} of the magnetic sensor j of the group β is (g_{βj}s_{βjx}, g_{βj}s_{βjy}, g_{βj}s_{βjz}), and the detected vector matrix K_{β} includes detected vectors k_{β1} to k_{βN} of N magnetic sensors of the group β as elements. The detected vector matrix K_{β} includes detected vectors perpendicular to each other, and thus it is possible to detect three-axis components in XYZ directions of an environmental magnetic field.

$${G}_{β} {S}_{β} = ( \begin{matrix}{g}_{β1} {s}_{β1 x} & {g}_{β1} {s}_{β1 y} & {g}_{β1} {s}_{β1 z} & 0 & 0 & … & 0 & 0 & 0 \\ 0 & 0 & 0 & {g}_{β2} {s}_{β2 x} & {g}_{β2} {s}_{β2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {g}_{β N} {s}_{β Nx} & {g}_{β N} {s}_{β Ny} & {g}_{β N} {s}_{β Nz}\end{matrix} ) = {K}_{β} \qquad ( 32 )$$

In addition, a computational observation value (estimated value) of the magnetic sensor j of the group β is represented by a calculated observation value l_{βj}′, and a calculated observation value vector l_{β}′ obtained by integrating calculated observation values l_{β1}′ to l_{βN}′ of N magnetic sensors of the group β is defined as the following expression (33). Meanwhile, in Expression (33), tr represents the transposition of the vector.

\vec{l}_{β}′=(_{β1}′ l_{β2}′ . . . l_{βN}′)^{tr} (33)

At this time, a relational expression of the following expression (34) is established between the calculated observation value vector l_{β}′, the gain matrix G_{β}, the detection axis matrix S_{β}, the positional information matrix P_{β}, the detected vector matrix K_{β}, the polynomial expression coefficient vector a, and the calculated magnetic field value vector B_{nβ}. In Expression (34), the relation of D_{β}=K_{β}P_{β} is established.

\vec{l}_{β}′=G₆₂S_{β}P_{β}\vec{a}=K_{β}P_{β}\vec{a}=D_{β}\vec{a}=K_{β}\vec{B}_{nβ} (34)

Similarly, an actual observation value (actual measurement value) of the magnetic sensor j of the group β is represented by a sensor observation value l_{βj}, and a sensor observation value vector l_{β} obtained by integrating sensor observation values l_{β1} to l_{βN} of N magnetic sensors of the group β is defined as the following expression (35). Meanwhile, in Expression (35), tr represents the transposition of the vector.

\vec{l}_{β}=(l_{β1} l_{β2} . . . l_{βN})^{tr} (35)

As shown in the following expression (36), a difference between the sensor observation value vector l_{β} and the calculated observation value vector l_{β}′ is set to be an observation value error vector v_{β}.

\vec{v}_{β}=\vec{l}_{β}−\vec{l}_{β}′ (36)

An optimization problem for obtaining a polynomial expression coefficient vector a for minimizing a norm ∥v_{β}∥ of the observation value error vector v_{β} defined as the following expression (37) is solved. Meanwhile, in Expression (37), the relation of v_{βj}=l_{βj}−l_{βj}′ is established.

∥\vec{v}_{β}∥=(Σⱼ₌₁^{N}|v_{βj}|²)^{1/2} (37)

In a case where the optimization problem is solved using a least-square method, a general solution of the polynomial expression coefficient vector a derived from the sensor observation value vector l_{β} is obtained by the following expression (38).

\vec{a}=(D_{β}^{T}D_{β})⁻¹D_{β}^{T}\vec{l}_{β} (38)

In addition, the polynomial expression coefficient vector a is expressed by the following expression (39) by using a pseudo inverse matrix D_{β}⁺ of D_{β}.

\vec{a}=D_{β}⁺\vec{l}_{β} (39)

Next, a calculated magnetic field value vector B_{nα} at the positions of M magnetic sensors of the group α is obtained by the calculation of a matrix by using the polynomial expression coefficient vector a obtained by Expression (39).

When a calculated magnetic field value of the environmental magnetic field bₙ at the position (xⱼ, yⱼ, zⱼ) of the magnetic sensor j of the group α is set to be (bₙⱼₓ, b_{njy}, b_{nz}), the calculated magnetic field value vector B_{nα} at the positions of M magnetic sensors of the group α is expressed by the following expression (40).

\vec{B}_{nα}=(bₙ₁ₓ b_{n1y} b_{n1z} bₙ₂ₓ b_{n2y} . . . b_{nMx} b_{nMy} b_{nMz}) (40)

A positional information matrix P_{α} of 3M×30 is defined as the following expression (41) on the basis of the defined secondary nonlinear polynomial expression (25).

$${P}_{α} = ( \begin{matrix}1 & {x}_{1} & … & {y}_{1}^{2} & {z}_{1}^{2} & 0 & 0 & … & 0 & 0 & 0 & 0 & … & 0 & 0 \\ 0 & 0 & … & 0 & 0 & 1 & {x}_{1} & … & {y}_{1}^{2} & {z}_{1}^{2} & 0 & 0 & … & 0 & 0 \\ 0 & 0 & … & 0 & 0 & 0 & 0 & … & 0 & 0 & 1 & {x}_{1} & … & {y}_{1}^{2} & {z}_{1}^{2} \\ 1 & {x}_{2} & … & {y}_{2}^{2} & {z}_{2}^{2} & 0 & 0 & … & 0 & 0 & 0 & 0 & … & 0 & 0 \\ 0 & 0 & … & 0 & 0 & 1 & {x}_{2} & … & {y}_{2}^{2} & {z}_{2}^{2} & 0 & 0 & … & 0 & 0 \\ 0 & 0 & … & 0 & 0 & 0 & 0 & … & 0 & 0 & 1 & {x}_{2} & … & {y}_{2}^{2} & {z}_{2}^{2} \\ 1 & {x}_{3} & … & {y}_{3}^{2} & {z}_{3}^{2} & 0 & 0 & … & 0 & 0 & 0 & 0 & … & 0 & 0 \\ ⋮ & ⋮ & ⋮ & ⋮ & ⋮ & ⋮ & ⋮ & ⋮ & ⋮ & ⋮ & ⋮ & ⋮ & ⋮ & ⋮ & ⋮ \\ 1 & {x}_{N} & … & {y}_{N}^{2} & {z}_{N}^{2} & 0 & 0 & … & 0 & 0 & 0 & 0 & … & 0 & 0 \\ 0 & 0 & … & 0 & 0 & 1 & {x}_{N} & … & {y}_{M}^{2} & {z}_{M}^{2} & 0 & 0 & … & 0 & 0 \\ 0 & 0 & … & 0 & 0 & 0 & 0 & … & 0 & 0 & 1 & {x}_{M} & … & {y}_{M}^{2} & {z}_{M}^{2}\end{matrix} ) \qquad ( 41 )$$

Here, the following relational expression (42) is established. That is, the positional information matrix P_{α} is a matrix for converting position vectors r₁=(x₁, y₁, z₁) to r_{M}=(x_{M}, y_{M}, z_{M}) of M magnetic sensors of the group α into the calculated magnetic field value vector B_{nα}.

\vec{B}_{nα}=P_{α}\vec{a} (42)

In addition, a gain matrix G_{α} including gains (equivalent to sensitivities) g_{α1} to g_{αN} of M magnetic sensors of the group α as elements is defined as the following expression (43). The gain matrix G_{α} is a square matrix of M×M.

$${G}_{α} = ( \begin{matrix}{g}_{α1} & 0 & … & 0 \\ ⋮ & ⋮ & ⋮ & ⋮ \\ 0 & {g}_{α2} & … & 0 \\ 0 & 0 & … & {g}_{α M}\end{matrix} ) \qquad ( 43 )$$

In addition, a detection axis orientation of the magnetic sensor j of the group α is represented by a unit vector s_{αj}=(s_{αjx}, s_{αjy}, s_{αjz}) on an XYZ orthogonal coordinate system, and a detection axis matrix S_{α} of M×3M which is obtained by integrating unit vectors s_{α1} to s_{αM} of the detection axis orientations of M magnetic sensors of the group α is defined as the following expression (44). Meanwhile, the relation of s_{αjx}²+s_{αjy}²+s_{αjz}²=1 is established.

$${S}_{α} = ( \begin{matrix}{s}_{α1 x} & {s}_{α1 y} & {s}_{α1 z} & 0 & 0 & … & 0 & 0 & 0 \\ 0 & 0 & 0 & {s}_{α2 x} & {s}_{α2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {s}_{α Mx} & {s}_{α My} & {s}_{α Mz}\end{matrix} ) \qquad ( 44 )$$

As shown in the following expression (45), a product of the gain matrix G_{α} and the detection axis matrix S_{α} is set to be a detected vector matrix K_{α}. Here, a detected vector k_{αj} of the magnetic sensor j of the group α is (g_{αj}s_{αjx}, g_{αj}s_{αjy}, g_{αj}s_{αjz}), and the detected vector matrix K_{α} includes detected vectors k_{α1} to k_{αM} of M magnetic sensors of the group α as elements.

$${G}_{α} {S}_{α} = ( \begin{matrix}{g}_{α1} {s}_{α1 x} & {g}_{α1} {s}_{α1 y} & {g}_{α1} {s}_{α1 z} & 0 & 0 & … & 0 & 0 & 0 \\ 0 & 0 & 0 & {g}_{α2} {s}_{α2 x} & {g}_{α2} {s}_{α2 y} & … & 0 & 0 & 0 \\ ⋮ & ⋮ & ⋮ & ⋮ & ⋮ & ⋮ & ⋮ & ⋮ & ⋮ \\ 0 & 0 & 0 & 0 & 0 & … & {g}_{α M} {s}_{α Mx} & {g}_{α M} {s}_{α My} & {g}_{α M} {s}_{α Mz}\end{matrix} ) = {K}_{α} \qquad ( 45 )$$

In addition, a computational observation value (estimated value including a magnetic field to be measured and an environmental magnetic field) of the magnetic sensor j of the group α is represented by a calculated observation value l_{αj}′, and a calculated observation value vector l_{α}′ obtained by integrating calculated observation values l_{α1}′ to l_{αM}′ of M magnetic sensors of the group α is defined as the following expression (46). Meanwhile, in Expression (46), tr represents the transposition of the vector.

\vec{l}_{α}′(l_{α1}′ l_{α2}′ . . . l_{αN}′)^{tr} (46)

Similarly, an actual observation value (actual measurement value) of the magnetic sensor j of the group α is represented by a sensor observation value l_{αj}, and a sensor observation value vector l_{α} obtained by integrating sensor observation values l_{α1} to l_{αM} of M magnetic sensors of the group α is defined as the following expression (47). Meanwhile, in Expression (47), tr represents the transposition of the vector.

\vec{l}_{α}=(l_{α1} l_{α2} . . . l_{αM})^{tr} (47)

At this time, a relational expression of the following expression (48) is established between the calculated observation value vector l_{α}′, the gain matrix G_{α}, the detection axis matrix S_{α}, the positional information matrix P_{α}, the detected vector matrix K_{α} and the polynomial expression coefficient vector a.

\vec{l}_{α}′=G_{α}S_{α}P_{α}\vec{a}=K_{α}P_{α}\vec{a} (48)

Here, it is assumed that M magnetic sensors of the group α are equivalent to the first magnetic sensors 11 and may measure only a magnetic field component perpendicular to, for example, a chest wall of a living body which is the test subject (living body) 9. Therefore, as illustrated in FIG. 9, detected vectors k_{αj} of the respective magnetic sensors j of the group α are aligned in the Z-axis direction, and a deviation θ of the detected vector k_{αj} with respect to the Z-axis is assumed to be small. That is, it is considered that all of the unit vectors s_{α1} to s_{αM} can be approximated to (0, 0, 1). Here, it is assumed that the gains g_{α1} to g_{αM} are different from each other.

At this time, the calculated observation value vector l_{α}′ expressed by Expression (48) is corrected by the gains g_{α1} to g_{αM}, that is, G_{α}⁻¹ is multiplied by the right side of Expression (48) from the left as shown in the following expression (49), and thus an approximate value lₙ′ of an environmental magnetic field (magnetic noise) at the positions of M magnetic sensors of the group α is obtained.

\vec{l}ₙ′=G_{α}⁻¹\vec{l}_{α}′=G_{α}⁻¹K_{α}P_{α}\vec{a}=S_{α}P_{α}\vec{a} (49)

In addition, an approximate value lₛₙ′ of the entire magnetic field (magnetic field to be measured (heart magnetic field)+environmental magnetic field (magnetic noise)) at the positions of M magnetic sensors of the group α is obtained by the following expression (50).

\vec{l}ₛₙ′=G_{α}⁻¹\vec{l}_{α} (50)

As shown in the following expression (51), an approximate value lₛ′ of a magnetic field to be measured (heart magnetic field) is obtained by taking a difference between the approximate value lₛₙ′ of the entire magnetic field (magnetic field to be measured (heart magnetic field)+environmental magnetic field (magnetic noise)) at the positions of M magnetic sensors of the group α and the approximate value lₙ′ of the environmental magnetic field (magnetic noise).

\vec{l}ₛ′=\vec{l}ₛₙ′−\vec{l}ₙ′ (51)

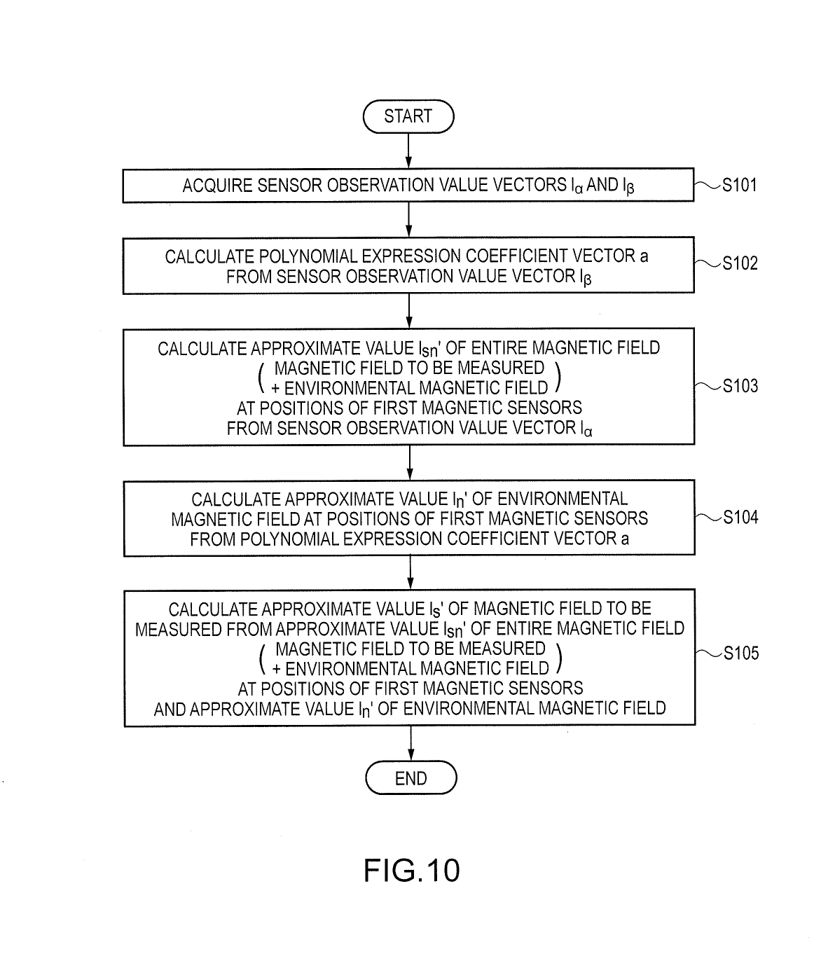

FIG. 10 is a flow chart illustrating an example of a procedure in which the magnetic field calculation unit 102 (see FIG. 4) of the processing apparatus 2 performs a magnetic field calculation process corresponding to the above-described magnetic field measurement method. Meanwhile, the magnetic field calculation process of FIG. 10 is performed in a state where the test subject (living body) 9 is lying on the table 4 (a state where a heart magnetic field or a brain magnetic field can be measured from the test subject (living body) 9). In addition, it is assumed that a calibration process of which the procedure is illustrated as an example in FIG. 6 is performed prior to the magnetic field calculation process of FIG. 10. That is, in the calibration process, it is assumed that the detected vector matrix K obtained by integrating the detected vector matrices K_{α} and K_{β} is updated (calculated) on the basis of the sensor observation value matrix L obtained by integrating the sensor observation value vectors l_{α} and l_{β}, and the values of the elements of the detected vector matrices K_{α} and K_{β} are stored in the storage unit 110.

In the example of FIG. 10, first, the magnetic field calculation unit 102 acquires the sensor observation value vectors l_{α} and l_{β} (step S101). Specifically, the magnetic field calculation unit 102 acquires measured values of the respective first magnetic sensors 11, and acquires the sensor observation value vector l_{α} obtained by integrating the measured values. In addition, the magnetic field calculation unit 102 acquires measured values of the respective second magnetic sensors 30, and acquires the sensor observation value vector l_{β} obtained by integrating the measured values.

Next, the magnetic field calculation unit 102 calculates the polynomial expression coefficient vector a from the sensor observation value vector l_{β} (step S102). Specifically, the magnetic field calculation unit 102 calculates the polynomial expression coefficient vector a by Expression (38) from the sensor observation value vector l_{β} acquired in step S101 and the detected vector matrix K_{β} and the positional information matrix P_{β} that are obtained in the calibration process. Meanwhile, in Expression (38), the relation of D_{β}=K_{β}P_{β} is established. In addition, the values of the elements of the positional information matrix P_{β} are stored in the storage unit 110 in advance, and the values of the elements of the detected vector matrix K_{β} are stored in the storage unit 110 in the calibration process.

Next, the magnetic field calculation unit 102 calculates the approximate value lₛₙ′ of the entire magnetic field (magnetic field to be measured+environmental magnetic field) at the positions of the first magnetic sensors 11 from the sensor observation value vector l_{α} (step S103). Specifically, all of the detected vectors k_{αj} of the respective first magnetic sensors 11 are aligned in the Z-axis direction, and the unit vector s_{αj}=(s_{αjx}, s_{αjy}, s_{αjz}) approximates to (0, 0, 1) on the assumption that a deviation θ of the detected vector k_{αj} with respect to the Z-axis is small. The magnetic field calculation unit 102 calculates the gain matrix G_{α} by Expression (43) and Expression (45) from (s_{αjx}, s_{αjy}, s_{αjz})≈(0, 0, 1) and the detected vector matrix K_{α}, and calculates an inverse matrix G_{α}⁻¹ thereof. Further, the magnetic field calculation unit 102 calculates the approximate value lₛₙ′ of the entire magnetic field (magnetic field to be measured+environmental magnetic field) at the positions of the first magnetic sensors 11 by Expression (50) from the sensor observation value vector l_{α} acquired in step S101 and the inverse matrix G_{α}⁻¹ of the gain matrix G_{α}. Meanwhile, the values of the elements of the detected vector matrix K_{α} are stored in the storage unit 110 in the calibration process.

Next, the magnetic field calculation unit 102 calculates the approximate value lₙ′ of the environmental magnetic field at the positions of the first magnetic sensors 11 from the polynomial expression coefficient vector a (step S104). Specifically, the magnetic field calculation unit 102 calculates the approximate value lₙ′ of the environmental magnetic field at the positions of the first magnetic sensors 11 by Expression (49) from the inverse matrix G_{α}⁻¹ of the gain matrix G_{α}, the detected vector matrix K_{α}, the positional information matrix P_{α}, and the polynomial expression coefficient vector a calculated in step S102. Meanwhile, the values of the elements of the positional information matrix P_{α} are stored in the storage unit 110 in advance.

Finally, the magnetic field calculation unit 102 calculates an approximate value lₛ′ of a magnetic field to be measured by Expression (51) from the approximate value lₛₙ′ of the entire magnetic field (magnetic field to be measured+environmental magnetic field) at the positions of the first magnetic sensors 11 which is calculated in step S103 and the approximate value lₙ′ of the environmental magnetic field at the positions of the first magnetic sensors 11 which is calculated in step S104 (step S105), and terminates the magnetic field measurement process.

1-7. Operational Effects

As described above, in this embodiment, the magnetic field calculation unit 102 estimates the distribution (polynomial expression coefficient vector a) of an environmental magnetic field on the basis of measured values (sensor observation value vector l_{β}) of N second magnetic sensors 30, and calculates a magnetic field to be measured (approximate value lₛ′ of a magnetic field to be measured) on the basis of the measured values (sensor observation value vector l_{α}) of M first magnetic sensors 11 and the estimated distribution (polynomial expression coefficient vector a) of an environmental magnetic field.

According to the magnetic field measurement apparatus 1 of this embodiment, the magnetic field calculation unit 102 can calculate a magnetic field (magnetic field including a magnetic field to be measured and an environmental magnetic field) at the positions of M first magnetic sensors 11 on the basis of measured values of M first magnetic sensors 11, and can calculate the environmental magnetic field at the positions of M first magnetic sensors 11 from the distribution of the environmental magnetic field which is estimated on the basis of the measured values of N second magnetic sensors 30. Therefore, for example, it is possible to calculate a difference between these magnetic fields or an approximate value thereof as the magnetic field to be measured. In this manner, according to the magnetic field measurement apparatus 1 of this embodiment, a relatively large environmental magnetic field is estimated with a high level of accuracy even when the magnetic field to be measured is a week magnetic field, and thus it is possible to perform the measurement with a sufficient accuracy.

In addition, in this embodiment, the magnetic field calculation unit 102 estimates a measured value of an environmental magnetic field which is obtained by the first magnetic sensor 11 (Expression (48)) on the basis of detected vectors (detected vector matrix K_{α}) of M first magnetic sensors 11 the positional information (positional information matrix P_{α}) of M first magnetic sensors 11 and the estimated distribution (polynomial expression coefficient vector a) of the environmental magnetic field, and calculates a magnetic field to be measured (approximate value lₛ′ of a magnetic field to be measured) on the basis of measured values (sensor observation value vector l_{α}) of M first magnetic sensors 11 and the estimated measured value (calculated observation value vector l_{α}′) of the environmental magnetic field.

In this manner, according to the magnetic field measurement apparatus 1 of this embodiment, the magnetic field calculation unit 102 can estimate measured values of an environmental magnetic field which are obtained by M first magnetic sensors 11 by using the estimated distribution of the environmental magnetic field and detected vectors (information regarding the directions of detection axes and gains) or positional information of M first magnetic sensors 11, and thus it is possible to calculate a magnetic field to be measured with a high level of accuracy.

In addition, in this embodiment, the magnetic field calculation unit 102 calculates an approximate value (lₛₙ′) of a magnetic field at the positions of M first magnetic sensors 11 on the basis of measured values (sensor observation value vector l_{α}) of M first magnetic sensors 11 and gains (gain matrix G_{α}) of M first magnetic sensors 11 (Expression (50)), calculates an approximate value (l_{α}′) of the environmental magnetic field at the positions of M first magnetic sensors 11 on the basis of an estimated measured value (calculated observation value vector l_{α}′) of the environmental magnetic field and gains (gain matrix G_{α}) of M first magnetic sensors 11 (Expression (49)), and calculates a magnetic field to be measured (approximate value lₛ′ of a magnetic field to be measured) by a difference between the approximate value (lₛₙ′) of the magnetic field at the positions of M first magnetic sensors 11 and the approximate value (lₙ′) of the environmental magnetic field at the positions of M first magnetic sensors 11 (Expression (51)).

In this manner, according to the magnetic field measurement apparatus 1 of this embodiment, the magnetic field calculation unit 102 can calculate a magnetic field (magnetic field including a magnetic field to be measured and an environmental magnetic field) in a detection axis direction at the positions of M first magnetic sensors by dividing measured values of M first magnetic sensors 11 by gains of M first magnetic sensors, and can calculate the environmental magnetic field in the detection axis direction at the positions of M first magnetic sensors 11 by dividing an estimated measured value of the environmental magnetic field by the gains of M first magnetic sensors 11. In this embodiment, a deviation between the direction of a detection axis of each of M first magnetic sensors 11 and a measurement direction (Z-axis direction) is small, and thus it is possible to set a calculated value of the magnetic field in the detection axis direction at the positions of M first magnetic sensors 11 to be an approximate value of the magnetic field at the positions of M first magnetic sensors 11 and to set a calculated value of the environmental magnetic field in the detection axis direction at the positions of M first magnetic sensors 11 to be an approximate value of the environmental magnetic field at the positions of M first magnetic sensors 11. Therefore, according to the magnetic field measurement apparatus 1 of this embodiment, even when the magnetic field to be measured cannot be correctly calculated due to the directions of the detection axes of all of the first magnetic sensors 11 being aligned, the magnetic field calculation unit 102 can perform approximation calculation of the magnetic field to be measured as a difference between the approximate value of the magnetic field (magnetic field including the magnetic field to be measured and the environmental magnetic field) at the positions of M first magnetic sensors 11 and the approximate value of the environmental magnetic field.

In addition, in this embodiment, the magnetic field calculation unit 102 estimates the distribution (polynomial expression coefficient vector a) of an environmental magnetic field on the basis of detected vectors (detected vector matrix K_{β}) of N second magnetic sensors 30, positional information (positional information matrix P_{β}) of N second magnetic sensors 30, and measured values (sensor observation value vector l_{β}) of N second magnetic sensors (Expression (38)).

In this manner, according to the magnetic field measurement apparatus 1 of this embodiment, the magnetic field calculation unit 102 can estimate the distribution of an environmental magnetic field with a high level of accuracy by using measured values of N second magnetic sensors and detected vectors (information regarding the directions of detection axes and gains) or positional information of N second magnetic sensors.

In addition, in this embodiment, the magnetic field calculation unit 102 estimates the distribution (polynomial expression coefficient vector a) of an environmental magnetic field by approximating the environmental magnetic field by a polynomial expression with the positions of M first magnetic sensors 11 as variables (Expression (42)) and calculating coefficients of the polynomial expression on the basis of measured values (sensor observation value vector l_{β}) of N second magnetic sensors 30.

In this manner, according to the magnetic field measurement apparatus 1 of this embodiment, the magnetic field calculation unit 102 can approximate an environmental magnetic field at the positions of M first magnetic sensors 11 with a high level of accuracy by using a polynomial expression with the positions of M first magnetic sensors 11 as variables, and can estimate the distribution of the environmental magnetic field at the positions of M first magnetic sensors 11 with a high level of accuracy in association with coefficients of the polynomial expression which are calculated on the basis of the measured values of N second magnetic sensors 30 with a high level of accuracy.

In addition, in this embodiment, the calibration unit 101 estimates the distribution (polynomial expression coefficient matrix A) of an environmental magnetic field on the basis of measured values of M first magnetic sensors 11 and measured values of N second magnetic sensors 30 (on the basis of a sensor observation value matrix L obtained by integrating sensor observation value vectors l_{α} and l_{β}), and calculates detected vectors of M first magnetic sensors 11 and detected vectors of N second magnetic sensors (a detected vector matrix K obtained by integrating a detected vector matrix K_{α} and a detected vector matrix K_{β}) on the basis of the estimated distribution (polynomial expression coefficient matrix A) of the environmental magnetic field.

In this manner, according to the magnetic field measurement apparatus 1 of this embodiment, the calibration unit 101 estimates the distribution of an environmental magnetic field in a space including M first magnetic sensors 11 and N second magnetic sensors 30 on the basis of measured values of M first magnetic sensors 11 and measured values of N second magnetic sensors 30 in a state where a magnetic field to be measured is not measured by M first magnetic sensors 11, and thus can calculate detected vectors (information regarding the directions of detection axes and gains) of M first magnetic sensors 11 or detected vectors (information regarding the directions of detection axes and gains) of N second magnetic sensors 30 with a high level of accuracy. Therefore, according to the magnetic field measurement apparatus 1 of this embodiment, the magnetic field calculation unit 102 can calculate a magnetic field to be measured with a high level of accuracy by using the detected vectors (information regarding the directions of detection axes and gains) of M first magnetic sensors 11 and the detected vectors (information regarding the directions of detection axes and gains) of N second magnetic sensors 30 which are calculated with a high level of accuracy.

### 2. Second Embodiment

In the magnetic field measurement apparatus 1 (magnetic field measurement method) according to the first embodiment, the nonlinear polynomial expression (25) showing the distribution of an environmental magnetic field is set without considering the original regularity of the environmental magnetic field at all. On the other hand, a magnetic field measurement apparatus 1 (magnetic field measurement method) according to a second embodiment is different from that of the first embodiment in that a rule of the divergence of an environmental magnetic field being zero is reflected, and is the same as that of the first embodiment in the other respects. That is, in the magnetic field measurement apparatus 1 (magnetic field measurement method) according to the second embodiment, it is assumed that the following expression (52) is established. A magnetic field calculation unit 102 calculates coefficients (polynomial expression coefficient vector a) of the polynomial expression (25) on the assumption that the divergence of the environmental magnetic field is zero.

$$div \vec{b} = \frac{\partial {b}_{nix}}{\partial {x}_{i}} + \frac{\partial {b}_{niy}}{\partial {y}_{i}} + \frac{\partial {b}_{niz}}{\partial {z}_{i}} = 0 \qquad ( 52 )$$

When a relationship between the coefficients is obtained by substituting Expression (25) for Expression (52), the following expression (53) is established.

aₓ₂+a_{y3}+a_{z4}+2aₓ₈xᵢ+a_{y5}xᵢ+a_{z7}xᵢ+2a_{y9}yᵢ+aₓ₅yᵢ+a_{z6}yᵢ2a_{z10}zᵢ+a_{y6}zᵢ+aₓ₇zᵢ=(aₓ₂+a_{y3}+a_{z4})+(2aₓ₈+a_{y5}+a_{z7})xᵢ+(2a_{y9}+aₓ₅+a_{z6})yᵢ+(2a_{z10}+a_{y6}+aₓ₇)zᵢ=0 (53)

Relational expressions of the following expression (54) are obtained using a fact that Expression (53) is an identity.

aₓ₂+a_{y3}+a_{z4}=0

2aₓ₈+a_{y5}+a_{z7}=0

2a_{y9}+aₓ₅+a_{z6}=0

2a_{z10}+a_{y6}+aₓ₇=0 (54)

Since four relational expressions shown in Expression (54) are obtained, the number of coefficients aₓ₁ to aₓ₁₀, a_{y1} to a_{y10}, and a_{z1} to a_{z10} which is 30 in the first embodiment is reduced to 26. The magnetic field calculation unit 102 calculates a magnetic field to be measured (approximate value lₛ′) in accordance with the procedure of FIG. 10. Therefore, according to the magnetic field measurement apparatus 1 (magnetic field measurement method) of the second embodiment, the amount of calculation of the magnetic field calculation unit 102 is reduced, or the accuracy of calculation of a magnetic field to be measured is improved.

### 3. Third Embodiment

In the magnetic field measurement apparatus 1 (magnetic field measurement method) according to the first embodiment, the nonlinear polynomial expression (25) showing the distribution of an environmental magnetic field is set without considering the original regularity of the environmental magnetic field at all. On the other hand, a magnetic field measurement apparatus 1 (magnetic field measurement method) according to a third embodiment is different from that of the first embodiment in that a rule of the rotation of an environmental magnetic field being zero is reflected, and is the same as that of the first embodiment in the other respects. That is, in the magnetic field measurement apparatus 1 (magnetic field measurement method) according to the third embodiment, it is assumed that the following expression (55) is established. A magnetic field calculation unit 102 calculates coefficients (polynomial expression coefficient vector a) of the polynomial expression (25) on the assumption that the rotation of the environmental magnetic field is zero. Meanwhile, a condition for setting a conduction current and a displacement current to be zero in a space to be measured is necessary in order to setting the rotation of the environmental magnetic field to be zero, and it is assumed that the condition is satisfied.

$$rot \vec{b} = ( \frac{\partial {b}_{niz}}{\partial {y}_{i}} - \frac{\partial {b}_{niy}}{\partial {z}_{i}} ) i + ( \frac{\partial {b}_{nix}}{\partial {z}_{i}} - \frac{\partial {b}_{niyz}}{\partial {x}_{i}} ) j + ( \frac{\partial {b}_{niy}}{\partial {x}_{i}} - \frac{\partial {b}_{nix}}{\partial {y}_{i}} ) k = 0 \qquad ( 55 )$$

When a relationship between the coefficients is obtained by substituting Expression (25) for Expression (55), the following expression (56) is established.

$$\frac{\partial {b}_{niz}}{\partial {y}_{i}} - \frac{\partial {b}_{niy}}{\partial {z}_{i}} = {a}_{z 3} - {a}_{y 4} + ( {a}_{z 5} - {a}_{y 7} ) {x}_{i} + ( 2 {a}_{z 9} - {a}_{y 6} ) {y}_{i} + ( {a}_{z 6} - 2 {a}_{y 10} ) {z}_{i} = 0 \\ \frac{\partial {b}_{nix}}{\partial {z}_{i}} - \frac{\partial {b}_{niz}}{\partial {x}_{i}} = {a}_{x 4} - {a}_{z 2} + ( {a}_{x 7} - 2 {a}_{z 8} ) {x}_{i} + ( {a}_{x 6} - {a}_{x 5} ) {y}_{i} + ( 2 {a}_{x 10} - {a}_{z 7} ) {z}_{i} = 0 \\ \frac{\partial {b}_{niy}}{\partial {x}_{i}} - \frac{\partial {b}_{nix}}{\partial {y}_{i}} = {a}_{y 2} - {a}_{x 3} + ( 2 {a}_{y 8} - {a}_{x 5} ) {x}_{i} + ( {a}_{y 5} - 2 {a}_{x 9} ) {y}_{i} + ( {a}_{y 7} - {a}_{x 6} ) {z}_{i} = 0 \qquad ( 56 )$$

Relational expressions of the following expression (57) are obtained using a fact that Expression (56) is an identity.

a_{z3}=a_{y4}

a_{z5}=a_{y7}

2a_{z9}=a_{y6}

a_{z6}=2a_{y10}

aₓ₄=a_{z2}

aₓ₇=2a_{z8}

aₓ₆=a_{z5}

2aₓ₁₀=a_{z7}

a_{y2}=aₓ₃

2a_{y8}=aₓ₃

a_{y5}=2aₓ₉

a_{y7}=aₓ₆ (57)

Twelve relational expressions shown in Expression (57) are obtained. Here, a_{y7}=aₓ₆ is obtained from a_{z5}=a_{y7} and aₓ₆=a_{z5}. Accordingly, since 11 relational expressions are actually obtained, the number of coefficients aₓ₁ to aₓ₁₀, a_{y1} to a_{y10}, and a_{z1} to a_{z10} which is 30 in the first embodiment is reduced to 19. A magnetic field calculation unit 102 calculates a magnetic field to be measured (approximate value lₛ′) in accordance with the procedure of FIG. 10. Therefore, according to the magnetic field measurement apparatus 1 (magnetic field measurement method) of the third embodiment, the amount of calculation of the magnetic field calculation unit 102 is reduced, or the accuracy of calculation of a magnetic field to be measured is improved.

Meanwhile, in this embodiment, the magnetic field calculation unit 102 may further calculate coefficients (polynomial expression coefficient vector a) of the polynomial expression (25) on the assumption that the divergence of an environmental magnetic field is zero, similar to the second embodiment. Thereby, the number of coefficients is reduced to fifteen due to a further reduction by four, and thus the amount of calculation of the magnetic field calculation unit 102 is further reduced, or the accuracy of calculation of a magnetic field to be measured is further improved.

### 4. Modification Example

The invention is not limited to this embodiment, and various modifications can be made without departing from the scope of the invention.

For example, in the above-described embodiments, the calibration unit 101 of the magnetic field measurement apparatus 1 performs a calibration process, but a calibration apparatus different from the magnetic field measurement apparatus 1 may perform a calibration process of the magnetic field measurement apparatus 1. That is, the processing apparatus 2 of the magnetic field measurement apparatus 1 may not include the calibration unit 101. In this case, the calibration apparatus writes detected vector matrices K_{α} and K_{β} obtained through the calibration process in the storage unit 110 of the processing apparatus 2, and the magnetic field measurement apparatus 1 (magnetic field calculation unit 102) may perform a magnetic field calculation process by using the detected vector matrices K_{α} and K_{β} written in the storage unit 110.

In addition, for example, in the above-described embodiments, the magnetic field measurement apparatus 1 measures a heart magnetic field or a brain magnetic field of the test subject 9 (living body), but the magnetic field measurement apparatus 1 may measure a biomagnetic field other than the heart magnetic field or the brain magnetic field, or may measure a magnetic field (week magnetic field) other than the biomagnetic field.

In addition, in the above-described embodiments, the computational expression (51) of an approximate value lₛ′ of a magnetic field to be measured (heart magnetic field) is derived on the assumption that detected vectors of magnetic sensors of the group α are aligned in the Z-axis direction, but a magnetic field to be measured (heart magnetic field) may be calculated as following on the assumption that the group α includes a plurality of magnetic sensors having detection axes in directions of two axes or three axes perpendicular to each other.

First, a polynomial expression coefficient vector a_{α} of a polynomial expression (for example, a secondary nonlinear polynomial expression) which shows the distribution of a magnetic field in the vicinity of M magnetic sensors of the group α is obtained by the following expression (58) similar to Expression (38) from the sensor observation value vector l_{α} shown in Expression (47). In Expression (58), the relation of D_{α}=K_{α}P_{α} is established. Meanwhile, the distribution of a heart magnetic field includes a higher-order term than the distribution of an environmental magnetic field, and thus the number of terms of the polynomial expression showing the distribution of the magnetic field in the vicinity of M magnetic sensors of the group α is not limited to being the same as the number of terms of Expression (25).

\vec{a}_{α}=(D_{α}^{T}D_{α})⁻¹D_{α}^{T}\vec{l}_{α} (58)

Next, a peripheral magnetic field Bₛₙ of M magnetic sensors of the group α is calculated by substituting Expression (58) for the following expression (59).

\vec{B}ₛₙ=P_{α}\vec{a}_{α} (59)

The peripheral magnetic field Bₛₙ includes an environmental magnetic field B_{nα} (obtained by Expression (42)) and a heart magnetic field Bₛ, and thus it is possible to calculate the heart magnetic field Bₛ by the following expression (60).

\vec{B}ₛ=\vec{B}ₛₙ−\vec{B}_{nα} (60)

The above-described embodiments and modification example are just examples, and are not limited thereto. For example, the embodiments and the modification example can also be appropriately combined with each other.

The invention includes substantially the same configurations (for example, configurations having the same functions, methods and results, or configurations having the same objects and effects) as the configurations described in the embodiments. In addition, the invention includes a configuration obtained by replacing non-essential portions in the configurations described in the embodiments. In addition, the invention includes a configuration that exhibits the same operational effects as those of the configurations described in the embodiment or a configuration capable of achieving the same objects. In addition, the invention includes a configuration obtained by adding the configurations described in the embodiments to known techniques.

What is claimed is:

1. A magnetic field measurement apparatus comprising:
at least one first magnetic sensor that measures a magnetic field including a magnetic field to be measured and an environmental magnetic field;
a plurality of second magnetic sensors that measure the environmental magnetic field; and
a magnetic field calculation unit that estimates distribution of the environmental magnetic field on the basis of measured values of the second magnetic sensors, and calculates the magnetic field to be measured on the basis of a measured value of the first magnetic sensor and the estimated distribution of the environmental magnetic field.

2. The magnetic field measurement apparatus according to claim 1,
wherein the magnetic field calculation unit estimates a measured value of the environmental magnetic field which is obtained by the first magnetic sensor on the basis of a detected vector of the first magnetic sensor, positional information of the first magnetic sensor, and the estimated distribution of the environmental magnetic field, and calculates the magnetic field to be measured on the basis of the measured value of the first magnetic sensor and the estimated measured value of the environmental magnetic field.

3. The magnetic field measurement apparatus according to claim 2,
wherein the magnetic field calculation unit calculates an approximate value of a magnetic field at a position of the first magnetic sensor on the basis of the measured value of the first magnetic sensor and a gain of the first magnetic sensor, calculates an approximate value of the environmental magnetic field at the position of the first magnetic sensor on the basis of the estimated measured value of the environmental magnetic field and the gain of the first magnetic sensor, and calculates the magnetic field to be measured on the basis of a difference between the approximate value of the magnetic field at the position of the first magnetic sensor and the approximate value of the environmental magnetic field at the position of the first magnetic sensor.

4. The magnetic field measurement apparatus according to claim 1,
wherein the magnetic field calculation unit estimates the distribution of the environmental magnetic field on the basis of detected vectors of the second magnetic sensors, positional information of the second magnetic sensors, and the measured values of the second magnetic sensors.

5. The magnetic field measurement apparatus according to claim 2, further comprising:
a calibration unit that estimates the distribution of the environmental magnetic field on the basis of the measured value of the first magnetic sensor and the measured values of the second magnetic sensors, and calculates the detected vector of the first magnetic sensor and the detected vectors of the second magnetic sensors on the basis of the estimated distribution of the environmental magnetic field.

6. The magnetic field measurement apparatus according to claim 1,
wherein the magnetic field calculation unit estimates the distribution of the environmental magnetic field by approximating the environmental magnetic field by a polynomial expression with the position of the first magnetic sensor as a variable and calculating coefficients of the polynomial expression on the basis of the measured values of the second magnetic sensors.

7. The magnetic field measurement apparatus according to claim 6,
wherein the magnetic field calculation unit calculates the coefficients of the polynomial expression on the assumption that divergence of the environmental magnetic field is zero.

8. The magnetic field measurement apparatus according to claim 6,
wherein the magnetic field calculation unit calculates the coefficients of the polynomial expression on the assumption that rotation of the environmental magnetic field is zero.

9. The magnetic field measurement apparatus according to claim 1,
wherein at least two of the detected vectors of the second magnetic sensors are perpendicular to each other.

10. The magnetic field measurement apparatus according to claim 1,
wherein each of the first magnetic sensor and the second magnetic sensors includes
a cell which accommodates alkali metal atoms and on which linearly polarized light is incident,
a polarized light separator that separates light emitted from the cell into light in a first axis direction and light in a second axis direction,
a first light detector that detects the light in the first axis direction, and
a second light detector that detects the light in the second axis direction.

11. The magnetic field measurement apparatus according to claim 10,
wherein the cells included in the second magnetic sensors are disposed on the same plane.

12. A magnetic field measurement method comprising:
acquiring a measured value of at least one first magnetic sensor that measures a magnetic field including a magnetic field to be measured and an environmental magnetic field;
acquiring measured values of a plurality of second magnetic sensors that measure the environmental magnetic field;
estimating distribution of the environmental magnetic field on the basis of the measured values of the second magnetic sensors; and
calculating the magnetic field to be measured on the basis of the measured value of the first magnetic sensor and the estimated distribution of the environmental magnetic field.
